(19) United States
(12) Patent Application Publication
(10) Pub. No.: US 2016/0083405 A1
(43) Pub. Date: Mar. 24, 2016

(54) TANTALUM- OR VANADIUM-CONTAINING FILM FORMING COMPOSITIONS AND VAPOR DEPOSITION OF TANTALUM- OR VANADIUM-CONTAINING FILMS

(71) Applicant: L'Air Liquide, Société Anonyme pour l'Etude et l'Exploitation des Procédés Georges Claude, Paris (FR)

(72) Inventors: Clément LANSALOT-MATRAS, Morrisville, PA (US); Julien Lieffrig, Soucy (FR); Jooho Lee, Seoul (KR); Wontae Noh, Seoul (KR)

(21) Appl. No.: 14/954,368

(22) Filed: Nov. 30, 2015

(51) Int. Cl. C07F 9/00; C23C 16/50; C23C 16/06; C23C 16/455

(52) U.S. Cl. CPC C07F 9/005; C23C 16/45525; C23C 16/50; C23C 16/06

(57) ABSTRACT

Tantalum- or Vanadium-containing film forming compositions are disclosed as well as methods of synthesizing the same and methods of forming Tantalum- or Vanadium-containing films on one or more substrates via vapor deposition processes using the disclosed Tantalum- or Vanadium-containing film forming compositions. The disclosed Tantalum- or Vanadium-containing film forming compositions comprising a precursor having the formula M(R₅Cp)₂(L), wherein M is Ta or V; each R is independently H, an alkyl group, or R′₃Si, with each R′ independently being H or an alkyl group; and L is selected from the group consisting of formamidinates (N^{R, R′}-fmd), amidinates (N^{R, R′}, R″-amd), or guanidinates (N^{R, R′}, N^{R″, R′″}-gnd).

### TECHNICAL FIELD

Tantalum- or Vanadium-containing film forming compositions are disclosed as well as methods of synthesizing the same and methods of forming Tantalum- or Vanadium-containing films on one or more substrates via vapor deposition processes using the disclosed Tantalum- or Vanadium-containing film forming compositions. The disclosed Tantalum- or Vanadium-containing film forming compositions comprising a precursor having the formula M(R₅Cp)₂(L), wherein M is Ta or V; each R is independently H, an alkyl group, or R′₃Si, with each R′ independently being H or an alkyl group; and L is selected from the group consisting of formamidinates (N^{R, R′}-fmd), amidinates (N^{R, R′}, R−-amd), or guanidinates (N^{R, R′}, N^{R″, R′″}-gnd).

### BACKGROUND

Tantalum-containing films have long been thought for variety of applications in the semiconductor, photovoltaic, LCD-TFT, and flat panel display industries. Tantalum Nitride (TaNₓ) films have been extensively utilized in various fields of technology. Traditionally these nitrides have been applied as hard and decorative coatings, but during the past decade they have increasingly been used as a diffusion barrier and adhesion/glue layers in microelectronic devices [Applied Surface Science 120 (1997) 199-212].

The resistance switching characteristics of TaₓO_{y} thin films show its potential applications for the next generation nonvolatile resistive random access memory (ReRAM) devices as well as for high-k capacitor applications such as a thin layer in-between ZrO₂ layers to reduce leak current and stabilize the phase.

Tantalum halides have been explored for the deposition of TaₓO_{y} (x=1-2; y=1-5) by CVD (Thin Solid Film 1999, 343-344, 111) or ALD (J. Vac. Sci. Technol. B 2003, 21, 2231, CVD 2009, 15, 269). Those precursors sometimes require high temperature and may not be appropriate as precursors due to the potential etching effect of the halides.

ALD of Ta₂O₅ with H₂O has shown a process window between 170° C. and 230° C., having amorphous phase at 600° C., as deposited and crystalline phase at 800° C. (Microelec. Eng. 2010, 87, 373).

Imido-type precursors are probably most well known and widely used to deposit Group 5 transition metal containing films. Mostly, they are in a liquid phase with high vapor pressure, which is big advantage in industry for vaporizing and transferring to a reaction chamber. Many derivates have been studied for CVD (CVD 2008, 14, 334, CVD 2000, 6, 223, ECS Tans. 2008, 16, 243) or ALD (Chem. Mater. 2012, 24, 975).

A need remains for developing liquid or low melting point (<50° C.), highly thermally stable, Tantalum-containing film forming compositions suitable for vapor phase film deposition with controlled thickness and composition at high temperature.

### NOTATION AND NOMENCLATURE

Certain abbreviations, symbols, and terms are used throughout the following description and claims, and include:

As used herein, the indefinite article “a” or “an” means one or more.

As used herein, the terms “approximately” or “about” mean ±10% of the value stated.

The standard abbreviations of the elements from the periodic table of elements are used herein. It should be understood that elements may be referred to by these abbreviations (e.g., V refers to Vanadium, Ta refers to Tantalum, N refers to nitrogen, C refers to carbon, etc.).

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R3.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation “Me” refers to a methyl group; the abbreviation “Et” refers to an ethyl group; the abbreviation “Pr” refers to a propyl group; the abbreviation “nPr” refers to a “normal” or linear propyl group; the abbreviation “iPr” refers to an isopropyl group; the abbreviation “Bu” refers to a butyl group; the abbreviation “nBu” refers to a “normal” or linear butyl group; the abbreviation “tBu” refers to a tert-butyl group, also known as 1,1-dimethylethyl; the abbreviation “sBu” refers to a sec-butyl group, also known as 1-methylpropyl; the abbreviation “iBu” refers to an iso-butyl group, also known as 2-methylpropyl; the abbreviation “amyl” refers to an amyl or pentyl group; the abbreviation “tAmyl” refers to a tert-amyl group, also known as 1,1-dimethylpropyl.

As used herein, the abbreviation “Cp” refers to cyclopentadienyl group; the abbreviation “Cp*” refers to a pentamethylcyclopentadienyl group; and the abbreviation “TMS” refers to trimethylsilyl (Me₃Si—).

As used herein, the abbreviation “N^{R, R′}-amd” or N^{R}R″-amd when R=R′ refers to the amidinate ligand [R—N—C(R″)═N—R′], wherein R, R′ and R″ are defined alkyl groups, such as Me, Et, nPr, iPr, nBu, iBi, sBu or tBu; the abbreviation “N^{R, R′}-fmd” or N^{R}-fmd when R═R′ refers to the formidinate ligand [R—N—C(H)═N—R′], wherein R and R′ are defined alkyl groups, such as Me, Et, nPr, iPr, nBu, iBi, sBu or tBu; the abbreviation “N^{R, R′}, N^{R″, R′″}-gnd” or N^{R}, N^{R″}-gnd when R═R′ and R″=R′″ refers to the guanidinate ligand [R—N—C(NR″R″′)═NR′], wherein R, R′, R″ and R″′ are defined alkyl group such as Me, Et, nPr, iPr, nBu, iBi, sBu or tBu. Although depicted here as having a double bond between the C and N of the ligand backbone, one of ordinary skill in the art will recognize that the amidinate, formidinate and guanidinate ligands do not contain a fixed double bond. Instead, one electron is delocalized amongst the N—C—N chain.

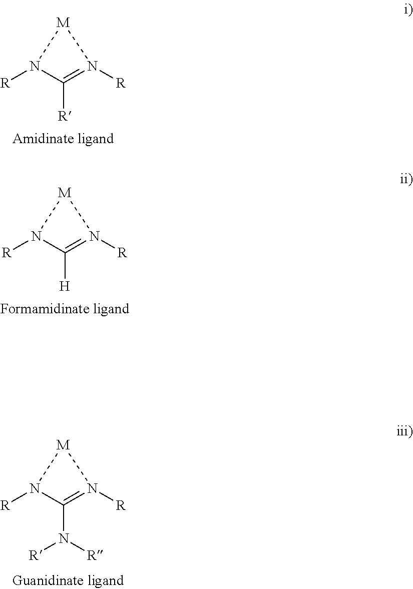

### SUMMARY

Disclosed are Tantalum-containing film forming compositions comprising a precursor having the formula:

Ta(R₅Cp)₂(L)

wherein each R is independently H, an alkyl group, or R′₃Si, with each R′ independently being H or an alkyl group; L is selected from the group consisting of formamidinates (N^{R, R′}-fmd), amidinates (N^{R, R′}, R″-amd), and guanidinates (N^{R, R′}, N^{R″, R′″}-gnd). The disclosed Tantalum-containing film forming compositions may include one or more of the following aspects:
each R independently being selected from H, Me, Et, nPr, iPr, tBu, sBu, iBu, nBu, tAmyl, SiMe₃, SiMe₂H, or SiH₂Me;
L being formamidinate (N^{R, R′}-fmd or N^{R}-fmd when R═R′);
the precursor being Ta(Cp)₂(N^{Me}-fmd);
the precursor being Ta(Cp)₂(N^{Et}-fmd);
the precursor being Ta(Cp)₂(N^{IRr}-fmd);
the precursor being Ta(Cp)₂(N^{nRr}-fmd);
the precursor being Ta(Cp)₂(N^{IBu}-fmd);
the precursor being Ta(Cp)₂(N^{nBu}-fmd);
the precursor being Ta(Cp)₂(N^{tBu}-fmd);
the precursor being Ta(Cp)₂(N^{sBu}-fmd);
the precursor being Ta(Cp)₂(N^{tAm}-fmd);
the precursor being Ta(Cp)₂(N^{TMS}-fmd);
the precursor being Ta(Cp)₂(N^{Et, tBu}-fmd);
the precursor being Ta(MeCp)₂(N^{Me}-fmd);
the precursor being Ta(MeCp)₂(N^{Et}-fmd);
the precursor being Ta(MeCp)₂(N^{iRr}-fmd);
the precursor being Ta(MeCp)₂(N^{nPr}-fmd);
the precursor being Ta(MeCp)₂(N^{iBu}-fmd);
the precursor being Ta(MeCp)₂(N^{nBu}-fmd);
the precursor being Ta(MeCp)₂(N^{tBu}-fmd);
the precursor being Ta(MeCp)₂(N^{sBu}-fmd);
the precursor being Ta(MeCp)₂(N^{tAm}-fmd);
the precursor being Ta(MeCp)₂(N^{TMS}-fmd);
the precursor being Ta(MeCp)₂(N^{Et, tBu}-fmd);
the precursor being Ta(EtCp)₂(N^{Me}-fmd);
the precursor being Ta(EtCp)₂(N^{Et}-fmd);
the precursor being Ta(EtCp)₂(N^{iPr}-fmd);
the precursor being Ta(EtCp)₂(N^{nPr}-fmd);
the precursor being Ta(EtCp)₂(N^{iBu}-fmd);
the precursor being Ta(EtCp)₂(N^{nBu}-fmd);
the precursor being Ta(EtCp)₂(N^{tBu}-fmd);
the precursor being Ta(EtCp)₂(N^{sBu}-fmd);
the precursor being Ta(EtCp)₂(N^{tAm}-fmd);
the precursor being Ta(EtCp)₂(N^{TMS}-fmd);
the precursor being Ta(EtCp)₂(N^{Et, tBu}-fmd);
the precursor being Ta(iPrCp)₂(N^{Me}-fmd);
the precursor being Ta(iPrCp)₂(N^{Et}-fmd);
the precursor being Ta(iPrCp)₂(N^{iPr}-fmd);
the precursor being Ta(iPrCp)₂(N^{nPr}-fmd);
the precursor being Ta(iPrCp)₂(N^{iBu}-fmd);
the precursor being Ta(iPrCp)₂(N^{nBu}-fmd);
the precursor being Ta(iPrCp)₂(N^{tBu}-fmd);
the precursor being Ta(iPrCp)₂(N^{sBu}-fmd);
the precursor being Ta(iPrCp)₂(N^{tAm}-fmd);
the precursor being Ta(iPrCp)₂(N^{TMS}-fmd);
the precursor being Ta(iPrCp)₂(N^{Et, tBu}-fmd);
the precursor being Ta(tBuCp)₂(N^{Me}-fmd);
the precursor being Ta(tBuCp)₂(N^{Et}-fmd);
the precursor being Ta(tBuCp)₂(N^{iPr}-fmd);
the precursor being Ta(tBuCp)₂(N^{nPr}-fmd);
the precursor being Ta(tBuCp)₂(N^{iBu}-fmd);
the precursor being Ta(tBuCp)₂(N^{nBu}-fmd);
the precursor being Ta(tBuCp)₂(N^{tBu}-fmd);
the precursor being Ta(tBuCp)₂(N^{sBu}-fmd);
the precursor being Ta(tBuCp)₂(N^{tAm}-fmd);
the precursor being Ta(tBuCp)₂(N^{TMS}-fmd);
the precursor being Ta(tBuCp)₂(N^{Et, tBu}-fmd);
the precursor being Ta(iPr₃Cp)₂(N^{Me}-fmd);
the precursor being Ta(iPr₃Cp)₂(N^{Et}-fmd);
the precursor being Ta(iPr₃Cp)₂(N^{iPr}-fmd);
the precursor being Ta(iPr₃Cp)₂(N^{nPr}-fmd);
the precursor being Ta(iPr₃Cp)₂(N^{iBu}-fmd);
the precursor being Ta(iPr₃Cp)₂(N^{nBu}-fmd);
the precursor being Ta(iPr₃Cp)₂(N^{tBu}-fmd);
the precursor being Ta(iPr₃Cp)₂(N^{sBu}-fmd);
the precursor being Ta(iPr₃Cp)₂(N^{tAm}-fmd);
the precursor being Ta(iPr₃Cp)₂(N^{TMS}-fmd);
the precursor being Ta(iPr₃Cp)₂(N^{Et, tBu}-fmd);
the precursor being Ta(Cp*)₂(N^{Me}-fmd);
the precursor being Ta(Cp*)₂(N^{Et}-fmd);
the precursor being Ta(Cp*)₂(N^{iPr}-fmd);
the precursor being Ta(Cp*)₂(N^{nPr}-fmd);
the precursor being Ta(Cp*)₂(N^{iBu}-fmd);
the precursor being Ta(Cp*)₂(N^{nBu}-fmd);
the precursor being Ta(Cp*)₂(N^{tBu}-fmd);
the precursor being Ta(Cp*)₂(N^{sBu}-fmd);
the precursor being Ta(Cp*)₂(N^{tAm}-fmd);
the precursor being Ta(Cp*)₂(N^{TMS}-fmd);
the precursor being Ta(Cp*)(N^{Et, tBu}-fmd);
the precursor being Ta(Me₃SiCp)₂(N^{Me}-fmd);
the precursor being Ta(Me₃SiCp)₂(N^{Et}-fmd);
the precursor being Ta(Me₃SiCp)₂(N^{iPr}-fmd);
the precursor being Ta(Me₃SiCp)₂(N^{nPr}-fmd);
the precursor being Ta(Me₃SiCp)₂(N^{iBu}-fmd);
the precursor being Ta(Me₃SiCp)₂(N^{nBu}-fmd);
the precursor being Ta(Me₃SiCp)₂(N^{tBu}-fmd);
the precursor being Ta(Me₃SiCp)₂(N^{sBu}-fmd);
the precursor being Ta(Me₃SiCp)₂(N^{tAm}-fmd);
the precursor being Ta(Me₃SiCp)₂(N^{TMS}-fmd);
the precursor being Ta(Me₃SiCp)₂(N^{Et, tBu}-fmd);
the precursor being Ta(Cp)(Cp*)(N^{Me}-fmd);
the precursor being Ta(Cp)(MeCp)(N^{Et}-fmd);
the precursor being Ta(Cp)(EtCp)(N^{iPr}-fmd);
the precursor being Ta(Cp)(iPrCp)(N^{nPr}-fmd);
the precursor being Ta(Cp)(nPrCp)(N^{iBu}-fmd);
the precursor being Ta(Cp)(iBuCp)(N^{nBu}-fmd);
the precursor being Ta(Cp)(tBuCp)(N^{tBu}-fmd);
the precursor being Ta(Cp)(tAmCp)(N^{sBu}-fmd);
the precursor being Ta(iPr₃Cp)(Cp)(N^{Et}-fmd);
L being amidinate (N^{R, R′} R″-amd or N^{R} R″-amd when R═R′);
the precursor being Ta(Cp)₂(N^{Me} Me-amd);
the precursor being Ta(Cp)₂(N^{Et} Me-amd);
the precursor being Ta(Cp)₂(N^{iPr} Me-amd);
the precursor being Ta(Cp)₂(N^{nPr} Me-amd);
the precursor being Ta(Cp)₂(N^{iBu} Me-amd);
the precursor being Ta(Cp)₂(N^{nBu} Me-amd);
the precursor being Ta(Cp)₂(N^{tBu} Me-amd);
the precursor being Ta(Cp)₂(N^{sBu} Me-amd);
the precursor being Ta(Cp)₂(N^{tAm} Me-amd);
the precursor being Ta(Cp)₂(N^{TMS} Me-amd);
the precursor being Ta(Cp)₂(N^{Et, tBu} Me-amd);
the precursor being Ta(MeCp)₂(N^{Me} Me-amd);
the precursor being Ta(MeCp)₂(N^{Et} Me-amd);
the precursor being Ta(MeCp)₂(N^{iPr} Me-amd);
the precursor being Ta(MeCp)₂(N^{nPr} Me-amd);
the precursor being Ta(MeCp)₂(N^{iBu} Me-amd);
the precursor being Ta(MeCp)₂(N^{nBu} Me-amd);
the precursor being Ta(MeCp)₂(N^{tBu} Me-amd);
the precursor being Ta(MeCp)₂(N^{sBu} Me-amd);
the precursor being Ta(MeCp)₂(N^{tAm} Me-amd);
the precursor being Ta(MeCp)₂(N^{TMS} Me-amd);
the precursor being Ta(MeCp)₂(N^{Et, tBu} Me-amd);
the precursor being Ta(EtCp)₂(N^{Me} Me-amd);
the precursor being Ta(EtCp)₂(N^{Et} Me-amd);
the precursor being Ta(EtCp)₂(N^{iPr} Me-amd);
the precursor being Ta(EtCp)₂(N^{nPr} Me-amd);
the precursor being Ta(EtCp)₂(N^{iBu} Me-amd);
the precursor being Ta(EtCp)₂(N^{nBu} Me-amd);
the precursor being Ta(EtCp)₂(N^{tBu} Me-amd);
the precursor being Ta(EtCp)₂(N^{sBu} Me-amd);
the precursor being Ta(EtCp)₂(N^{tAm} Me-amd);
the precursor being Ta(EtCp)₂(N^{TMS} Me-amd);
the precursor being Ta(EtCp)₂(N^{Et, tBu} Me-amd);
the precursor being Ta(iPrCp)₂(N^{Me} Me-amd);
the precursor being Ta(iPrCp)₂(N^{Et} Me-amd);
the precursor being Ta(iPrCp)₂(N^{iPr} Me-amd);
the precursor being Ta(iPrCp)₂(N^{nPr} Me-amd);
the precursor being Ta(iPrCp)₂(N^{iBu} Me-amd);
the precursor being Ta(iPrCp)₂(N^{nBu} Me-amd);
the precursor being Ta(iPrCp)₂(N^{tBu} Me-amd);
the precursor being Ta(iPrCp)₂(N^{sBu} Me-amd);
the precursor being Ta(iPrCp)₂(N^{tAm} Me-amd);
the precursor being Ta(iPrCp)₂(N^{TMS} Me-amd);
the precursor being Ta(iPrCp)₂(N^{Et, tBu} Me-amd);
the precursor being Ta(tBuCp)₂(N^{Me} Me-amd);
the precursor being Ta(tBuCp)₂(N^{Et} Me-amd);
the precursor being Ta(tBuCp)₂(N^{iPr} Me-amd);
the precursor being Ta(tBuCp)₂(N^{nPr} Me-amd);
the precursor being Ta(tBuCp)₂(N^{iBu} Me-amd);
the precursor being Ta(tBuCp)₂(N^{nBu} Me-amd);
the precursor being Ta(tBuCp)₂(N^{tBu} Me-amd);
the precursor being Ta(tBuCp)₂(N^{sBu} Me-amd);
the precursor being Ta(tBuCp)₂(N^{tAm} Me-amd);
the precursor being Ta(tBuCp)₂(N^{TMS} Me-amd);
the precursor being Ta(tBuCp)₂(N^{Et, tBu} Me-amd);
the precursor being Ta(iPr₃Cp)₂(N^{Me} Me-amd);
the precursor being Ta(iPr₃Cp)₂(N^{Et} Me-amd);
the precursor being Ta(iPr₃Cp)₂(N^{iPr} Me-amd);
the precursor being Ta(iPr₃Cp)₂(N^{nPr} Me-amd);
the precursor being Ta(iPr₃Cp)₂(N^{iBu} Me-amd);
the precursor being Ta(iPr₃Cp)₂(N^{nBu} Me-amd);
the precursor being Ta(iPr₃Cp)₂(N^{tBu} Me-amd);
the precursor being Ta(iPr₃Cp)₂(N^{sBu} Me-amd);
the precursor being Ta(iPr₃Cp)₂(N^{tAm} Me-amd);
the precursor being Ta(iPr₃Cp)₂(N^{TMS} Me-amd);
the precursor being Ta(iPr₃Cp)₂(N^{Et, tBu} Me-amd);
the precursor being Ta(Cp*)₂(N^{Me} Me-amd);
the precursor being Ta(Cp*)₂(N^{Et} Me-amd);
the precursor being Ta(Cp*)₂(N^{iPr} Me-amd);
the precursor being Ta(Cp*)₂(N^{nPr} Me-amd);
the precursor being Ta(Cp*)₂(N^{iBu} Me-amd);
the precursor being Ta(Cp*)₂(N^{nBu} Me-amd);
the precursor being Ta(Cp*)₂(N^{tBu} Me-amd);
the precursor being Ta(Cp*)₂(N^{sBu} Me-amd);
the precursor being Ta(Cp*)₂(N^{tAm} Me-amd);
the precursor being Ta(Cp*)₂( N^{TMS} Me-amd);
the precursor being Ta(Cp*)₂(N^{Et, tBu} Me-amd);
the precursor being Ta(Me₃SiCp)₂(N^{Me} Me-amd);
the precursor being Ta(Me₃SiCp)₂(N^{Et} Me-amd);
the precursor being Ta(Me₃SiCp)₂(N^{iPr} Me-amd);
the precursor being Ta(Me₃SiCp)₂(N^{nPr} Me-amd);
the precursor being Ta(Me₃SiCp)₂(N^{iBu} Me-amd);
the precursor being Ta(Me₃SiCp)₂(N^{nBu} Me-amd);
the precursor being Ta(Me₃SiCp)₂(N^{tBu} Me-amd);
the precursor being Ta(Me₃SiCp)₂(N^{sBu} Me-amd);
the precursor being Ta(Me₃SiCp)₂(N^{tAm} Me-amd);
the precursor being Ta(Me₃SiCp)₂(N^{TMS} Me-amd);
the precursor being Ta(Me₃SiCp)₂(N^{Et, tBu} Me-amd);
the precursor being Ta(Cp)(Cp*)(N^{Me} Me-amd);
the precursor being Ta(Cp)(MeCp)(N^{Et} Me-amd);
the precursor being Ta(Cp)(EtCp)(N^{iPr} Me-amd);
the precursor being Ta(Cp)(iPrCp)(N^{nPr} Me-amd);
the precursor being Ta(Cp)(nPrCp)(N^{iBu} Me-amd);
the precursor being Ta(Cp)(iBuCp)(N^{nBu} Me-amd);
the precursor being Ta(Cp)(tBuCp)(N^{tBu} Me-amd);
the precursor being Ta(Cp)(tAmCp)(N^{sBu} Me-amd);
the precursor being Ta(Cp)(iPr₃Cp)(N^{iPr} Me-amd);
the precursor being Ta(Cp)₂(N^{iPr} Et-amd);
the precursor being Ta(Cp)₂(N^{iPr} nPr-amd);
the precursor being Ta(Cp)₂(N^{iPr} iPr-amd);
the precursor being Ta(Cp)₂(N^{iPr} nBu-amd);
the precursor being Ta(Cp)₂(N^{iPr} tBu-amd);
the precursor being Ta(Cp)₂(N^{iPr} sBu-amd);
the precursor being Ta(Cp)₂(N^{iPr} iBu-amd);
the precursor being Ta(MeCp)₂(N^{iPr} Et-amd);
the precursor being Ta(MeCp)₂(N^{iPr} nPr-amd);
the precursor being Ta(MeCp)₂(N^{iPr} iPr-amd);
the precursor being Ta(MeCp)₂(N^{iPr} nBu-amd);
the precursor being Ta(MeCp)₂(N^{iPr} tBu-amd);
the precursor being Ta(MeCp)₂(N^{iPr} sBu-amd);
the precursor being Ta(MeCp)₂(N^{iPr} iBu-amd);
the precursor being Ta(EtCp)₂(N^{iPr} Et-amd);
the precursor being Ta(EtCp)₂(N^{iPr} nPr-amd);
the precursor being Ta(EtCp)₂(N^{iPr} iPr-amd);
the precursor being Ta(EtCp)₂(N^{iPr} nBu-amd);
the precursor being Ta(EtCp)₂(N^{iPr} tBu-amd);
the precursor being Ta(EtCp)₂(N^{iPr} sBu-amd);
the precursor being Ta(EtCp)₂(N^{iPr} iBu-amd);
the precursor being Ta(iPr₃Cp)₂(N^{iPr} Et-amd);
the precursor being Ta(iPr₃Cp)₂(N^{iPr} nPr-amd);
the precursor being Ta(iPr₃Cp)₂(N^{iPr} iPr-amd);
the precursor being Ta(iPr₃Cp)₂(N^{iPr} nBu-amd);
the precursor being Ta(iPr₃Cp)₂(N^{iPr} tBu-amd);
the precursor being Ta(iPr₃Cp)₂(N^{iPr} sBu-amd);
the precursor being Ta(iPr₃Cp)₂(N^{iPr} iBu-amd);
L being guanidinate (N^{R, R′},N^{R″,R′41} -gnd or N^{R}, N^{R″}-gnd when R═R′ and R″═R′″);
the precursor being Ta(Cp)₂(N^{Me}, N^{Me}-gnd);
the precursor being Ta(Cp)₂(N^{Et}, N^{Me}-gnd);
the precursor being Ta(Cp)₂(N^{iPr}, N^{Me}-gnd);
the precursor being Ta(Cp)₂(N^{nPr}, N^{Me}-gnd);
the precursor being Ta(Cp)₂(N^{iBu}, N^{Me}-gnd);
the precursor being Ta(Cp)₂(N^{nBu}, N^{Me}-gnd);
the precursor being Ta(Cp)₂(N^{tBu}, N^{Me}-gnd);
the precursor being Ta(Cp)₂(N^{sBu}, N^{Me}-gnd);
the precursor being Ta(Cp)₂(N^{tAm}, N^{Me}-gnd);
the precursor being Ta(Cp)₂(N^{TMS}, N^{Me}-gnd);
the precursor being Ta(Cp)₂(N^{Et, tBu}, N^{Me}-gnd);
the precursor being Ta(MeCp)₂(N^{Me}, N^{Me}-gnd);
the precursor being Ta(MeCp)₂(N^{Et}, N^{Me}-gnd);
the precursor being Ta(MeCp)₂(N^{iPr}, N^{Me}-gnd);
the precursor being Ta(MeCp)₂(N^{nPr}, N^{Me}-gnd);
the precursor being Ta(MeCp)₂(N^{iBu}, N^{Me}-gnd);
the precursor being Ta(MeCp)₂(N^{nBu}, N^{Me}-gnd);
the precursor being Ta(MeCp)₂(N^{tBu}, N^{Me}-gnd);
the precursor being Ta(MeCp)₂(N^{sBu}, N^{Me}-gnd);
the precursor being Ta(MeCp)₂(N^{tAm}, N^{Me}-gnd);
the precursor being Ta(MeCp)₂(N^{TMS}, N^{Me}-gnd);
the precursor being Ta(MeCp)₂(N^{Et, tBu} N^{Me}-gnd);
the precursor being Ta(EtCp)₂(N^{Me}, N^{Me}-gnd);
the precursor being Ta(EtCp)₂(N^{Et}, N^{Me}-gnd);
the precursor being Ta(EtCp)₂(N^{iPr}, N^{Me}-gnd);
the precursor being Ta(EtCp)₂(N^{nPr}, N^{Me}-gnd);
the precursor being Ta(EtCp)₂(N^{iBu}, N^{Me}-gnd);
the precursor being Ta(EtCp)₂(N^{nBu}, N^{Me}-gnd);
the precursor being Ta(EtCp)₂(N^{tBu}, N^{Me}-gnd);
the precursor being Ta(EtCp)₂(N^{sBu}, N^{Me}-gnd);
the precursor being Ta(EtCp)₂(N^{tAm}, N^{Me}-gnd);
the precursor being Ta(EtCp)₂(N^{TMS}, N^{Me}-gnd);
the precursor being Ta(EtCp)₂(N^{Et, tBu}, N^{Me}-gnd);
the precursor being Ta(iPrCp)₂(N^{Me}, N^{Me}-gnd);
the precursor being Ta(iPrCp)₂(N^{Et}, N^{Me}-gnd);
the precursor being Ta(iPrCp)₂(N^{iPr}, N^{Me}-gnd);
the precursor being Ta(iPrCp)₂(N^{nPr}, N^{Me}-gnd);
the precursor being Ta(iPrCp)₂(N^{iBu}, N^{Me}-gnd);
the precursor being Ta(iPrCp)₂(N^{nBu}, N^{Me}-gnd);
the precursor being Ta(iPrCp)₂(N^{tBu}, N^{Me}-gnd);
the precursor being Ta(iPrCp)₂(N^{sBu}, N^{Me}-gnd);
the precursor being Ta(iPrCp)₂(N^{tAm}, N^{Me}-gnd);
the precursor being Ta(iPrCp)₂(N^{TMS}, N^{Me}-gnd);
the precursor being Ta(iPrCp)₂(N^{Et, tBu} N^{Me}-gnd);
the precursor being Ta(tBuCp)₂(N^{Me}, N^{Me}-gnd);
the precursor being Ta(tBuCp)₂(N^{Et}, N^{Me}-gnd);
the precursor being Ta(tBuCp)₂(N^{iPr}, N^{Me}-gnd);
the precursor being Ta(tBuCp)₂(N^{nPr}, N^{Me}-gnd);
the precursor being Ta(tBuCp)₂(N^{iBu}, N^{Me}-gnd);
the precursor being Ta(tBuCp)₂(N^{nBu}, N^{Me}-gnd);
the precursor being Ta(tBuCp)₂(N^{tBu}, N^{Me}-gnd);
the precursor being Ta(tBuCp)₂(N^{sBu}, N^{Me}-gnd);
the precursor being Ta(tBuCp)₂(N^{tAm}, N^{Me}-gnd);
the precursor being Ta(tBuCp)₂(N^{TMS}, N^{Me}-gnd);
the precursor being Ta(tBuCp)₂(N^{Et, tBu}, N^{Me}-gnd);
the precursor being Ta(iPr₃Cp)₂(N^{Me}, N^{Me}-gnd);
the precursor being Ta(iPr₃Cp)₂(N^{Et}, N^{Me}-gnd);
the precursor being Ta(iPr₃Cp)₂(N^{iPr}, N^{Me}-gnd);
the precursor being Ta(iPr₃Cp)₂(N^{nPr}, N^{Me}-gnd);
the precursor being Ta(iPr₃Cp)₂(N^{iBu}, N^{Me}-gnd);
the precursor being Ta(iPr₃Cp)₂(N^{nBu}, N^{Me}-gnd);
the precursor being Ta(iPr₃Cp)₂(N^{tBu}, N^{Me}-gnd);
the precursor being Ta(iPr₃Cp)₂(N^{sBu}, N^{Me}-gnd);
the precursor being Ta(iPr₃Cp)₂(N^{tAm}, N^{Me}-gnd);
the precursor being Ta(iPr₃Cp)₂(N^{TMS}, N^{Me}-gnd);
the precursor being Ta(iPr₃Cp)₂(N^{Et, tBu}, N^{Me}-gnd);
the precursor being Ta(Cp*)₂(N^{Me}, N^{Me}-gnd);
the precursor being Ta(Cp*)₂(N^{Et}, N^{Me}-gnd);
the precursor being Ta(Cp*)₂(N^{iPr}, N^{Me}-gnd);
the precursor being Ta(Cp*)₂(N^{nPr}, N^{Me}-gnd);
the precursor being Ta(Cp*)₂(N^{iBu}, N^{Me}gnd);
the precursor being Ta(Cp*)₂(N^{nBu}, N^{Me}-gnd);
the precursor being Ta(Cp*)₂(N^{tBu}, N^{Me}-gnd);
the precursor being Ta(Cp*)₂(N^{sBu}, N^{Me}-gnd);
the precursor being Ta(Cp*)₂(N^{tAm}, N^{Me}-gnd);
the precursor being Ta(Cp*)₂(N^{TMS}, N^{Me}-gnd);
the precursor being Ta(Cp*)₂(N^{Et, tBu}, N^{Me}-gnd);
the precursor being Ta(Me₃SiCp)₂(N^{Me}, N^{Me}-gnd);
the precursor being Ta(Me₃SiCp)₂(N^{Et}, N^{Me}-gnd);
the precursor being Ta(Me₃SiCp)₂(N^{iPr}, N^{Me}-gnd);
the precursor being Ta(Me₃SiCp)₂(N^{nPr}, N^{Me}-gnd);
the precursor being Ta(Me₃SiCp)₂(N^{iBu}, N^{Me}-gnd);
the precursor being Ta(Me₃SiCp)₂(N^{nBu}, N^{Me}-gnd);
the precursor being Ta(Me₃SiCp)₂(N^{tBu}, N^{Me}-gnd);
the precursor being Ta(Me₃SiCp)₂(N^{sBu}, N^{Me}-gnd);
the precursor being Ta(Me₃SiCp)₂(N^{tAm}, N^{Me}-gnd);
the precursor being Ta(Me₃SiCp)₂(N^{TMS}, N^{Me}-gnd);
the precursor being Ta(Me₃SiCp)₂(N^{Et, tBu}, N^{Me}-gnd);
the precursor being Ta(Cp)(iPr₃Cp)(N^{Me}, N^{Me}-gnd);
the precursor being Ta(Cp)(Cp*)(N^{Me}, N^{Me}-gnd);
the precursor being Ta(Cp)(MeCp)(N^{Et}, N^{Me}-gnd);
the precursor being Ta(Cp)(EtCp)(N^{iPr}, N^{Me}-gnd);
the precursor being Ta(Cp)(iPrCp)(N^{nPr}, N^{Me}-gnd);
the precursor being Ta(Cp)(nPrCp)(N^{iBu}, N^{Me}-gnd);
the precursor being Ta(Cp)(iBuCp)(N^{nBu}, N^{Me}-gnd);
the precursor being Ta(Cp)(tBuCp)(N^{tBu}, N^{Me}-gnd);
the precursor being Ta(Cp)(tAmCp)(N^{sBu}, N^{Me}-gnd);
the precursor being Ta(Cp)₂(N^{iPr}, N^{Me, Et}-gnd);
the precursor being Ta(Cp)₂(N^{iPr}, N^{Et}-gnd);
the precursor being Ta(Cp)₂(N^{iPr}, N^{nPr}-gnd);
the precursor being Ta(Cp)₂(N^{iPr}, N^{iPr}-gnd);
the precursor being Ta(MeCp)₂(N^{iPr}, N^{Me, Et}-gnd);
the precursor being Ta(MeCp)₂(N^{iPr}, N^{Et}-gnd);
the precursor being Ta(MeCp)₂(N^{iPr}, N^{nPr}-gnd);
the precursor being Ta(MeCp)₂(N^{iPr}, N^{iPr}-gnd);
the precursor being Ta(EtCp)₂(N^{iPr}, N^{Me, Et}-gnd);
the precursor being Ta(EtCp)₂(N^{iPr}, N^{Et}-gnd);
the precursor being Ta(EtCp)₂(N^{iPr}, N^{nPr}-gnd);
the precursor being Ta(EtCp)₂(N^{iPr}, N^{iPr}-gnd);
the Tantalum-containing film forming composition comprising between approximately 95.0% w/w and approximately 100.0% w/w of the precursor;
the Tantalum-containing film forming composition comprising between approximately 5% w/w and approximately 50% w/w of the precursor;
the Tantalum-containing film forming composition comprising between approximately 0.0% w/w and approximately 5.0% w/w impurities;
the Tantalum-containing film forming composition comprising between approximately 0.0% w/w and approximately 2.0% w/w impurities;
the Tantalum-containing film forming composition comprising between approximately 0.0% w/w and approximately 1.0% w/w impurities;
the impurities including carbodiimides; formamidine; amidine; guanidine; alkylamines; dialkylamines; alkylimines; cyclopentadiene; dicyclopentadiene; THF; ether; pentane; cyclohexane; heptanes; benzene; toluene; chlorinated metal compounds; lithium, sodium, or potassium formamidinate; lithium, sodium, or potassium amidinate; lithium, sodium, or potassium guanidinate; and lithium, sodium, or potassium cyclopentadienyl;
the Tantalum-containing film forming composition comprising between approximately 0.0% w/w and approximately 2.0% w/w carbodiimide impurities;
the Tantalum-containing film forming composition comprising between approximately 0.0% w/w and approximately 2.0% w/w alkylamine impurities;
the Tantalum-containing film forming composition comprising between approximately 0.0% w/w and approximately 2.0% w/w alkylimine impurities;
the Tantalum-containing film forming composition comprising between approximately 0.0% w/w and approximately 2.0% w/w cyclopentadiene impurities;
the Tantalum-containing film forming composition comprising between approximately 0.0% w/w and approximately 2.0% w/w dicyclopentadiene impurities;
the Tantalum-containing film forming composition comprising between approximately 0.0% w/w and approximately 2.0% w/w THF impurities;
the Tantalum-containing film forming composition comprising between approximately 0.0% w/w and approximately 2.0% w/w ether impurities;
the Tantalum-containing film forming composition comprising between approximately 0.0% w/w and approximately 2.0% w/w pentane impurities;
the Tantalum-containing film forming composition comprising between approximately 0.0% w/w and approximately 2.0% w/w cyclohexane impurities;
the Tantalum-containing film forming composition comprising between approximately 0.0% w/w and approximately 2.0% w/w heptanes impurities;
the Tantalum-containing film forming composition comprising between approximately 0.0% w/w and approximately 2.0% w/w benzene impurities;
the Tantalum-containing film forming composition comprising between approximately 0.0% w/w and approximately 2.0% w/w toluene impurities;
the Tantalum-containing film forming composition comprising between approximately 0.0% w/w and approximately 2.0% w/w chlorinated metal compound impurities;
the Tantalum-containing film forming composition comprising between approximately 0.0% w/w and approximately 2.0% w/w lithium, sodium, or potassium formamidinate impurities;
the Tantalum-containing film forming composition comprising between approximately 0.0% w/w and approximately 2.0% w/w lithium, sodium, or potassium amidinate impurities;
the Tantalum-containing film forming composition comprising between approximately 0.0% w/w and approximately 2.0% w/w lithium, sodium, or potassium guanidinate impurities;
the Tantalum-containing film forming composition comprising between approximately 0.0% w/w and approximately 2.0% w/w lithum, sodium, or potassium cyclopentadienyl impurities;
the Tantalum-containing film forming composition comprising between approximately 0 ppbw and approximately 1 ppmw metal impurities;
the Tantalum-containing film forming composition comprising between approximately 0 ppbw and approximately 500 ppbw metal impurities;
the metal impurities including Aluminum (Al), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Indium (In), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti), Uranium (U), and Zinc (Zn);
the Tantalum-containing film forming composition comprising between approximately 0 ppbw and approximately 500 ppbw Al impurities;
the Tantalum-containing film forming composition comprising between approximately 0 ppbw and approximately 500 ppbw As impurities;
the Tantalum-containing film forming composition comprising between approximately 0 ppbw and approximately 500 ppbw Ba impurities;
the Tantalum-containing film forming composition comprising between approximately 0 ppbw and approximately 500 ppbw Be impurities;
the Tantalum-containing film forming composition comprising between approximately 0 ppbw and approximately 500 ppbw Bi impurities;
the Tantalum-containing film forming composition comprising between approximately 0 ppbw and approximately 500 ppbw Cd impurities;
the Tantalum-containing film forming composition comprising between approximately 0 ppbw and approximately 500 ppbw Ca impurities;
the Tantalum-containing film forming composition comprising between approximately 0 ppbw and approximately 500 ppbw Cr impurities;
the Tantalum-containing film forming composition comprising between approximately 0 ppbw and approximately 500 ppbw Co impurities;
the Tantalum-containing film forming composition comprising between approximately 0 ppbw and approximately 500 ppbw Cu impurities;
the Tantalum-containing film forming composition comprising between approximately 0 ppbw and approximately 500 ppbw Ga impurities;
the Tantalum-containing film forming composition comprising between approximately 0 ppbw and approximately 500 ppbw Ge impurities;
the Tantalum-containing film forming composition comprising between approximately 0 ppbw and approximately 500 ppbw Hf impurities;
the Tantalum-containing film forming composition comprising between approximately 0 ppbw and approximately 500 ppbw Zr impurities;
the Tantalum-containing film forming composition comprising between approximately 0 ppbw and approximately 500 ppbw In impurities;
the Tantalum-containing film forming composition comprising between approximately 0 ppbw and approximately 500 ppbw Fe impurities;
the Tantalum-containing film forming composition comprising between approximately 0 ppbw and approximately 500 ppbw Pb impurities;
the Tantalum-containing film forming composition comprising between approximately 0 ppbw and approximately 500 ppbw Li impurities;
the Tantalum-containing film forming composition comprising between approximately 0 ppbw and approximately 500 ppbw Mg impurities;
the Tantalum-containing film forming composition comprising between approximately 0 ppbw and approximately 500 ppbw Mn impurities;
the Tantalum-containing film forming composition comprising between approximately 0 ppbw and approximately 500 ppbw W impurities;
the Tantalum-containing film forming composition comprising between approximately 0 ppbw and approximately 500 ppbw Ni impurities;
the Tantalum-containing film forming composition comprising between approximately 0 ppbw and approximately 500 ppbw K impurities;
the Tantalum-containing film forming composition comprising between approximately 0 ppbw and approximately 500 ppbw Na impurities;
the Tantalum-containing film forming composition comprising between approximately 0 ppbw and approximately 500 ppbw Sr impurities;
the Tantalum-containing film forming composition comprising between approximately 0 ppbw and approximately 500 ppbw Th impurities;
the Tantalum-containing film forming composition comprising between approximately 0 ppbw and approximately 500 ppbw Sn impurities;
the Tantalum-containing film forming composition comprising between approximately 0 ppbw and approximately 500 ppbw Ti impurities;
the Tantalum-containing film forming composition comprising between approximately 0 ppbw and approximately 500 ppbw U impurities; and
the Tantalum-containing film forming composition comprising between approximately 0 ppbw and approximately 500 ppbw Zn impurities.

Also disclosed are Vanadium-containing film forming compositions comprising a precursor having the formula:

V(R₅Cp)₂(L)

wherein each R is independently H, an alkyl group, or R′₃Si, with each R′ independently being H or an alkyl group; L is selected from the group consisting of formamidinates (N^{R, R′}-fmd), amidinates (N^{R, R′}, R″-amd), and guanidinates (N^{R, R′}, N^{R″, R′″}- gnd). The disclosed Vanadium-containing film forming compositions may include one or more of the following aspects:
each R independently being selected from H, Me, Et, nPr, iPr, tBu, sBu, iBu, nBu, tAmyl, SiMe₃, SiMe₂H, or SiH₂Me;
L being formamidinate (N^{R, R′}-fmd or N^{R}-fmd when R═R′);
the precursor being V(Cp)₂(N^{Me}-fmd);
the precursor being V(Cp)₂(N^{Et}-fmd);
the precursor being V(Cp)₂(N^{iPr}-fmd);
the precursor being V(Cp)₂(N^{nPr}-fmd);
the precursor being V(Cp)₂(N^{iBu}-fmd);
the precursor being V(Cp)₂(N^{nBu}-fmd);
the precursor being V(Cp)₂(N^{tBu}-fmd);
the precursor being V(Cp)₂(N^{sBu}-fmd);
the precursor being V(Cp)₂(N^{tAm}-fmd);
the precursor being V(Cp)₂(N^{TMS}-fmd);
the precursor being V(Cp)₂(N^{Et, tBu}-fmd);
the precursor being V(MeCp)₂(N^{Me}-fmd);
the precursor being V(MeCp)₂(N^{Et}-fmd);
the precursor being V(MeCp)₂(N^{iPr}-fmd);
the precursor being V(MeCp)₂(N^{nPr}-fmd);
the precursor being V(MeCp)₂(N^{iBu}-fmd);
the precursor being V(MeCp)₂(N^{nBu}-fmd);
the precursor being V(MeCp)₂(N^{tBu}-fmd);
the precursor being V(MeCp)₂(N^{sBu}-fmd);
the precursor being V(MeCp)₂(N^{tAm}-fmd);
the precursor being V(MeCp)₂(N^{TMS}-fmd);
the precursor being V(MeCp)₂(N^{Et, tBu}-fmd);
the precursor being V(EtCp)₂(N^{Me}-fmd);
the precursor being V(EtCp)₂(N^{Et}-fmd);
the precursor being V(EtCp)₂(N^{iPr}-fmd);
the precursor being V(EtCp)₂(N^{nPr}-fmd);
the precursor being V(EtCp)₂(N^{iBu}-fmd);
the precursor being V(EtCp)₂(N^{nBu}-fmd);
the precursor being V(EtCp)₂(N^{tBu}-fmd);
the precursor being V(EtCp)₂(N^{sBu}-fmd);
the precursor being V(EtCp)₂(N^{tAm}-fmd);
the precursor being V(EtCp)₂(N^{TMS}-fmd);
the precursor being V(EtCp)₂(N^{Et, tBu}-fmd);
the precursor being V(iPrCp)₂(N^{Me}-fmd);
the precursor being V(iPrCp)₂(N^{Et}-fmd);
the precursor being V(iPrCp)₂(N^{iPr}-fmd);
the precursor being V(iPrCp)₂(N^{nPr}-fmd);
the precursor being V(iPrCp)₂(N^{iBu}-fmd);
the precursor being V(iPrCp)₂(N^{nBu}-fmd);
the precursor being V(iPrCp)₂(N^{tBu}-fmd);
the precursor being V(iPrCp)₂(N^{sBu}-fmd);
the precursor being V(iPrCp)₂(N^{tAm}-fmd);
the precursor being V(iPrCp)₂(N^{TMS}-fmd);
the precursor being V(iPrCp)₂(N^{Et, tBu}-fmd);
the precursor being V(tBuCp)₂(N^{Me}-fmd);
the precursor being V(tBuCp)₂(N^{Et}-fmd);
the precursor being V(tBuCp)₂(N^{iPr}-fmd);
the precursor being V(tBuCp)₂(N^{nPr}-fmd);
the precursor being V(tBuCp)₂(N^{iBu}-fmd);
the precursor being V(tBuCp)₂(N^{nBu}-fmd);
the precursor being V(tBuCp)₂(N^{tBu}-fmd);
the precursor being V(tBuCp)₂(N^{sBu}-fmd);
the precursor being V(tBuCp)₂(N^{tAm}-fmd);
the precursor being V(tBuCp)₂(N^{TMS}-fmd);
the precursor being V(tBuCp)₂(N^{Et, tBu}-fmd);
the precursor being V(iPr₃Cp)₂(N^{Me}-fmd);
the precursor being V(iPr₃Cp)₂(N^{Et}-fmd);
the precursor being V(iPr₃Cp)₂(N^{iPr}-fmd);
the precursor being V(iPr₃Cp)₂(N^{nPr}-fmd);
the precursor being V(iPr₃Cp)₂(N^{iBu}-fmd);
the precursor being V(iPr₃Cp)₂(N^{nBu}-fmd);
the precursor being V(iPr₃Cp)₂(N^{tBu}-fmd);
the precursor being V(iPr₃Cp)₂(N^{sBu}-fmd);
the precursor being V(iPr₃Cp)₂(N^{tAm}-fmd);
the precursor being V(iPr₃Cp)₂(N^{TMS}-fmd);
the precursor being V(iPr₃Cp)₂(N^{Et, tBu}-fmd);
the precursor being V(Cp*)₂(N^{Me}-fmd);
the precursor being V(Cp*)₂(N^{Et}-fmd);
the precursor being V(Cp*)₂(N^{iPr}-fmd);
the precursor being V(Cp*)₂(N^{nPr}-fmd);
the precursor being V(Cp*)₂(N^{iBu}-fmd);
the precursor being V(Cp*)₂(N^{nBu}-fmd);
the precursor being V(Cp*)₂(N^{tBu}-fmd);
the precursor being V(Cp*)₂(N^{sBu}-fmd);
the precursor being V(Cp*)₂(N^{tAm}-fmd);
the precursor being V(Cp*)₂(N^{TMS}-fmd);
the precursor being V(Cp*)(N^{Et, tBu}-fmd);
the precursor being V(Me₃SiCp)₂(N^{Me}-fmd);
the precursor being V(Me₃SiCp)₂(N^{Et}-fmd);
the precursor being V(Me₃SiCp)₂(N^{iPr}-fmd);
the precursor being V(Me₃SiCp)₂(N^{nPr}-fmd);
the precursor being V(Me₃SiCp)₂(N^{iBu}-fmd);
the precursor being V(Me₃SiCp)₂(N^{nBu}-fmd);
the precursor being V(Me₃SiCp)₂(N^{tBu}-fmd);
the precursor being V(Me₃SiCp)₂(N^{sBu}-fmd);
the precursor being V(Me₃SiCp)₂(N^{tAm}-fmd);
the precursor being V(Me₃SiCp)₂(N^{TMS}-fmd);
the precursor being V(Me₃SiCp)₂(N^{Et, tBu}-fmd);
the precursor being V(Cp)(Cp*)(N^{Me}-fmd);
the precursor being V(Cp)(MeCp)(N^{Et}-fmd);
the precursor being V(Cp)(EtCp)(N^{iPr}-fmd);
the precursor being V(Cp)(iPrCp)(N^{nPr}-fmd);
the precursor being V(Cp)(nPrCp)(N^{iBu}-fmd);
the precursor being V(Cp)(iBuCp)(N^{nBu}-fmd);
the precursor being V(Cp)(tBuCp)(N^{tBu}-fmd);
the precursor being V(Cp)(tAmCp)(N^{sBu}-fmd);
the precursor being V(iPr₃Cp)(Cp)(N^{Et}-fmd);
L being amidinate (N^{R, R′} R″-amd or N^{R} R″-amd when R═R′);
the precursor being V(Cp)₂(N^{Me} Me-amd);
the precursor being V(Cp)₂(N^{Et} Me-amd);
the precursor being V(Cp)₂(N^{iPr} Me-amd);
the precursor being V(Cp)₂(N^{nPr} Me-amd);
the precursor being V(Cp)₂(N^{iBu} Me-amd);
the precursor being V(Cp)₂(N^{nBu} Me-amd);
the precursor being V(Cp)₂(N^{tBu} Me-amd);
the precursor being V(Cp)₂(N^{sBu} Me-amd);
the precursor being V(Cp)₂(N^{tAm} Me-amd);
the precursor being V(Cp)₂(N^{TMS} Me-amd);
the precursor being V(Cp)₂(N^{Et, tBu} Me-amd);
the precursor being V(MeCp)₂(N^{Me} Me-amd);
the precursor being V(MeCp)₂(N^{Et} Me-amd);
the precursor being V(MeCp)₂(N^{iPr} Me-amd);
the precursor being V(MeCp)₂(N^{nPr} Me-amd);
the precursor being V(MeCp)₂(N^{iBu} Me-amd);
the precursor being V(MeCp)₂(N^{nBu} Me-amd);
the precursor being V(MeCp)₂(N^{tBu} Me-amd);
the precursor being V(MeCp)₂(N^{sBu} Me-amd);
the precursor being V(MeCp)₂(N^{tAm} Me-amd);
the precursor being V(MeCp)₂(N^{TMS} Me-amd);
the precursor being V(MeCp)₂(N^{Et, tBu} Me-amd);
the precursor being V(EtCp)₂(N^{Me} Me-amd);
the precursor being V(EtCp)₂(N^{Et} Me-amd);
the precursor being V(EtCp)₂(N^{iPr} Me-amd);
the precursor being V(EtCp)₂(N^{nPr} Me-amd);
the precursor being V(EtCp)₂(N^{iBu} Me-amd);
the precursor being V(EtCp)₂(N^{nBu} Me-amd);
the precursor being V(EtCp)₂(N^{tBu} Me-amd);
the precursor being V(EtCp)₂(N^{sBu} Me-amd);
the precursor being V(EtCp)₂(N^{tAm} Me-amd);
the precursor being V(EtCp)₂(N^{TMS} Me-amd);
the precursor being V(EtCp)₂(N^{Et, tBu} Me-amd);
the precursor being V(iPrCp)₂(N^{Me} Me-amd);
the precursor being V(iPrCp)₂(N^{Et} Me-amd);
the precursor being V(iPrCp)₂(N^{iPr} Me-amd);
the precursor being V(iPrCp)₂(N^{nPr} Me-amd);
the precursor being V(iPrCp)₂(N^{iBu} Me-amd);
the precursor being V(iPrCp)₂(N^{nBu} Me-amd);
the precursor being V(iPrCp)₂(N^{tBu} Me-amd);
the precursor being V(iPrCp)₂(N^{sBu} Me-amd);
the precursor being V(iPrCp)₂(N^{tAm} Me-amd);
the precursor being V(iPrCp)₂(N^{TMS} Me-amd);
the precursor being V(iPrCp)₂(N^{Et, tBu} Me-amd);
the precursor being V(tBuCp)₂(N^{Me} Me-amd);
the precursor being V(tBuCp)₂(N^{Et} Me-amd);
the precursor being V(tBuCp)₂(N^{iPr} Me-amd);
the precursor being V(tBuCp)₂(N^{nPr} Me-amd);
the precursor being V(tBuCp)₂(N^{iBu} Me-amd);
the precursor being V(tBuCp)₂(N^{nBu} Me-amd);
the precursor being V(tBuCp)₂(N^{tBu} Me-amd);
the precursor being V(tBuCp)₂(N^{sBu} Me-amd);
the precursor being V(tBuCp)₂(N^{tAm} Me-amd);
the precursor being V(tBuCp)₂(N^{TMS} Me-amd);
the precursor being V(tBuCp)₂(N^{Et, tBu} Me-amd);
the precursor being V(iPr₃Cp)₂(N^{Me} Me-amd);
the precursor being V(iPr₃Cp)₂(N^{Et} Me-amd);
the precursor being V(iPr₃Cp)₂(N^{iPr} Me-amd);
the precursor being V(iPr₃Cp)₂(N^{nPr} Me-amd);
the precursor being V(iPr₃Cp)₂(N^{iBu} Me-amd);
the precursor being V(iPr₃Cp)₂(N^{nBu} Me-amd);
the precursor being V(iPr₃Cp)₂(N^{tBu} Me-amd);
the precursor being V(iPr₃Cp)₂(N^{sBu} Me-amd);
the precursor being V(iPr₃Cp)₂(N^{tAm} Me-amd);
the precursor being V(iPr₃Cp)₂(N^{TMS} Me-amd);
the precursor being V(iPr₃Cp)₂(N^{Et, tBu} Me-amd);
the precursor being V(Cp*)₂(N^{Me} Me-amd);
the precursor being V(Cp*)₂(N ^{Et} Me-amd);
the precursor being V(Cp*)₂(N^{iPr} Me-amd);
the precursor being V(Cp*)₂(N^{nPr} Me-amd);
the precursor being V(Cp*)₂(N^{iBu} Me-amd);
the precursor being V(Cp*)₂(N^{nBu} Me-amd);
the precursor being V(Cp*)₂(N^{tBu} Me-amd);
the precursor being V(Cp*)₂(N^{sBu} Me-amd);
the precursor being V(Cp*)₂(N^{tAm} Me-amd);
the precursor being V(Cp*)₂(N^{TMS} Me-amd);
the precursor being V(Cp*)₂(N^{Et, tBu} Me-amd);
the precursor being V(Me₃SiCp)₂(N^{Me} Me-amd);
the precursor being V(Me₃SiCp)₂(N^{Et} Me-amd);
the precursor being V(Me₃SiCp)₂(N^{iPr} Me-amd);
the precursor being V(Me₃SiCp)₂(N^{nPr} Me-amd);
the precursor being V(Me₃SiCp)₂(N^{iBu} Me-amd);
the precursor being V(Me₃SiCp)₂(N^{nBu} Me-amd);
the precursor being V(Me₃SiCp)₂(N^{tBu} Me-amd);
the precursor being V(Me₃SiCp)₂(N^{eBu} Me-amd);
the precursor being V(Me₃SiCp)₂(N^{tAm} Me-amd);
the precursor being V(Me₃SiCp)₂(N^{TMS} Me-amd);
the precursor being V(Me₃SiCp)₂(N^{Et, tBu} Me-amd);
the precursor being V(Cp)(Cp*)(N^{Me} Me-amd);
the precursor being V(Cp)(MeCp)(N^{Et} Me-amd);
the precursor being V(Cp)(EtCp)(N^{iPr} Me-amd);
the precursor being V(Cp)(iPrCp)(N^{nPr} Me-amd);
the precursor being V(Cp)(nPrCp)(N^{iBu} Me-amd);
the precursor being V(Cp)(iBuCp)(N^{nBu} Me-amd);
the precursor being V(Cp)(tBuCp)(N^{tBu} Me-amd);
the precursor being V(Cp)(tAmCp)(N^{sBu} Me-amd);

the precursor being V(Cp)(iPr₃Cp)(N^{iPr} Me-amd);
the precursor being V(Cp)₂(N^{iPr} Et-amd);

the precursor being V(Cp)₂(N^{iPr} nPr-amd);
the precursor being V(Cp)₂(N^{iPr} iPr-amd);
the precursor being V(Cp)₂(N^{iPr} nBu-amd);
the precursor being V(Cp)₂(N^{iPr} tBu-amd);
the precursor being V(Cp)₂(N^{iPr} sBu-amd);
the precursor being V(Cp)₂(N^{iPr} iBu-amd);
the precursor being V(MeCp)₂(N^{iPr} Et-amd);
the precursor being V(MeCp)₂(N^{iPr} nPr-amd);
the precursor being V(MeCp)₂(N^{iPr} iPr-amd);
the precursor being V(MeCp)₂(N^{iPr} nBu-amd);
the precursor being V(MeCp)₂(N^{iPr} tBu-amd);
the precursor being V(MeCp)₂(N^{iPr} sBu-amd);
the precursor being V(MeCp)₂(N^{iPr} iBu-amd);
the precursor being V(EtCp)₂(N^{iPr} Et-amd);
the precursor being V(EtCp)₂(N^{iPr} nPr-amd);
the precursor being V(EtCp)₂(N^{iPr} iPr-amd);
the precursor being V(EtCp)₂(N^{iPr} nBu-amd);
the precursor being V(EtCp)₂(N^{iPr} tBu-amd);
the precursor being V(EtCp)₂(N^{iPr} sBu-amd);
the precursor being V(EtCp)₂(N^{iPr} iBu-amd);
the precursor being V(iPr₃Cp)₂(N^{iPr} Et-amd);
the precursor being V(iPr₃Cp)₂(N^{iPr} nPr-amd);
the precursor being V(iPr₃Cp)₂(N^{iPr} iPr-amd);
the precursor being V(iPr₃Cp)₂(N^{iPr} nBu-amd);
the precursor being V(iPr₃Cp)₂(N^{iPr} tBu-amd);
the precursor being V(iPr₃Cp)₂(N^{iPr} sBu-amd);
the precursor being V(iPr₃Cp)₂(N^{iPr} iBu-amd);
L being guanidinate (N^{R, R′}, N^{R″, R′″}-gnd or N^{R}, N^{R″}-gnd when R═R′ and R″═R′″);
the precursor being V(Cp)₂(N^{Me}, N^{Me}-gnd);
the precursor being V(Cp)₂(N^{Et}, N^{Me}-gnd);
the precursor being V(Cp)₂(N^{iPr}, N^{Me}-gnd);
the precursor being V(Cp)₂(N^{nPr}, N^{Me}-gnd);
the precursor being V(Cp)₂(N^{iBu}, N^{Me}-gnd);
the precursor being V(Cp)₂(N^{nBu}, N^{Me}-gnd);
the precursor being V(Cp)₂(N^{tBu}, N^{Me}-gnd);
the precursor being V(Cp)₂(N^{sBu}, N^{Me}-gnd);
the precursor being V(Cp)₂(N^{tAm}, N^{Me}-gnd);
the precursor being V(Cp)₂(N^{TMS}, N^{Me}-gnd);
the precursor being V(Cp)₂(N^{Et, tBu}, N^{Me}-gnd);
the precursor being V(MeCp)₂(N^{Me}, N^{Me}-gnd);
the precursor being V(MeCp)₂(N^{Et}, N^{Me}-gnd);
the precursor being V(MeCp)₂(N^{iPr}, N^{Me}-gnd);
the precursor being V(MeCp)₂(N^{nPr}, N^{Me}-gnd);
the precursor being V(MeCp)₂(N^{iBu}, N^{Me}-gnd);
the precursor being V(MeCp)₂(N^{nBu}, N^{Me}-gnd);
the precursor being V(MeCp)₂(N^{tBu}, N^{Me}-gnd);
the precursor being V(MeCp)₂(N^{sBu}, N^{Me}-gnd);
the precursor being V(MeCp)₂(N^{tAm}, N^{Me}-gnd);
the precursor being V(MeCp)₂(N^{Tms}, N^{Me}-gnd);
the precursor being V(MeCp)₂(N^{Et, tBu}, N^{Me}-gnd);
the precursor being V(EtCp)₂(N^{Me}, N^{Me}-gnd);
the precursor being V(EtCp)₂(N^{Et}, N^{Me}-gnd);
the precursor being V(EtCp)₂(N^{iPr}, N^{Me}-gnd);
the precursor being V(EtCp)₂(N^{nPr}, N^{Me}-gnd);
the precursor being V(EtCp)₂(N^{iBu}, N^{Me}-gnd);
the precursor being V(EtCp)₂(N^{nBu}, N^{Me}-gnd);
the precursor being V(EtCp)₂(N^{tBu}, N^{Me}-gnd);
the precursor being V(EtCp)₂(N^{sBu}, N^{Me}-gnd);
the precursor being V(EtCp)₂(N^{tAm}, N^{Me}-gnd);
the precursor being V(EtCp)₂(N^{TMS}, N^{Me}-gnd);
the precursor being V(EtCp)₂(N^{Et, tBu}, N^{Me}-gnd);
the precursor being V(iPrCp)₂(N^{Me}, N^{Me}-gnd);
the precursor being V(iPrCp)₂(N^{Et}, N^{Me}-gnd);
the precursor being V(iPrCp)₂(N^{iPr}, N^{Me}-gnd);
the precursor being V(iPrCp)₂(N^{nPr}, N^{Me}-gnd);
the precursor being V(iPrCp)₂(N^{iBu}, N^{Me}-gnd);
the precursor being V(iPrCp)₂(N^{nBu}, N^{Me}-gnd);
the precursor being V(iPrCp)₂(N^{tBu}, N^{Me}-gnd);
the precursor being V(iPrCp)₂(N^{sBu}, N^{Me}-gnd);
the precursor being V(iPrCp)₂(N^{tAm}, N^{Me}-gnd);
the precursor being V(iPrCp)₂(N^{TMS}, N^{Me-}gnd);
the precursor being V(iPrCp)₂(N^{Et, tBu}, N^{Me-}gnd);
the precursor being V(tBuCp)₂(N^{Me}, N^{Me}-gnd);
the precursor being V(tBuCp)₂(N^{Et}, N^{Me}-gnd);
the precursor being V(tBuCp)₂(N^{iPr}, N^{Me}-gnd);
the precursor being V(tBuCp)₂(N^{nPr}, N^{Me}-gnd);
the precursor being V(tBuCp)₂(N^{iBu}, N^{Me}-gnd);
the precursor being V(tBuCp)₂(N^{nBu}, N^{Me}-gnd);
the precursor being V(tBuCp)₂(N^{tBu}, N^{Me}-gnd);
the precursor being V(tBuCp)₂(N^{sBu}, N^{Me}-gnd);
the precursor being V(tBuCp)₂(N^{tAm}, N^{Me}-gnd);
the precursor being V(tBuCp)₂(N^{TMS}, N^{Me}-gnd);
the precursor being V(tBuCp)₂(N^{Et, tBu}, N^{Me}-gnd);
the precursor being V(iPr₃Cp)₂(N^{Me}, N^{Me}-gnd);
the precursor being V(iPr₃Cp)₂(N^{Et}, N^{Me}-gnd);
the precursor being V(iPr₃Cp)₂(N^{iPr}, N^{Me}-gnd);
the precursor being V(iPr₃Cp)₂(N^{nPr}, N^{Me}-gnd);
the precursor being V(iPr₃Cp)₂(N^{iBu}, N^{Me}-gnd);
the precursor being V(iPr₃Cp)₂(N^{nBu}, N^{Me}-gnd);
the precursor being V(iPr₃Cp)₂(N^{tBu}, N^{Me}-gnd);
the precursor being V(iPr₃Cp)₂(N^{sBu}, N^{Me}-gnd);
the precursor being V(iPr₃Cp)₂(N^{tAm}, N^{Me}-gnd);
the precursor being V(iPr₃Cp)₂(N^{TMS}, N^{Me}-gnd);
the precursor being V(iPr₃Cp)₂(N^{Et, tBu}, N^{Me}-gnd);
the precursor being V(Cp*)₂(N^{Me}, N^{Me}-gnd);
the precursor being V(Cp*)₂(N^{Et}, N^{Me}-gnd);
the precursor being V(Cp*)₂(N^{iPr}, N^{Me}-gnd);
the precursor being V(Cp*)₂(N^{nPr}, N^{Me}-gnd);
the precursor being V(Cp*)₂(N^{iBu}, N^{Me}-gnd);
the precursor being V(Cp*)₂(N^{nBu}, N^{Me}-gnd);
the precursor being V(Cp*)₂(N^{tBu}, N^{Me}-gnd);
the precursor being V(Cp*)₂(N^{sBu}, N^{Me}-gnd);
the precursor being V(Cp*)₂(N^{tAm}, N^{Me}-gnd);
the precursor being V(Cp*)₂(N^{TMS}, N^{Me}-gnd);
the precursor being V(Cp*)₂(N^{Et, tBu}, N^{Me}-gnd);
the precursor being V(Me₃SiCp)₂(N^{Me}, N^{Me}-gnd);
the precursor being V(Me₃SiCp)₂(N^{Et}, N^{Me}-gnd);
the precursor being V(Me₃SiCp)₂(N^{iPr}, N^{Me}-gnd);
the precursor being V(Me₃SiCp)₂(N^{nPr}, N^{Me}-gnd);
the precursor being V(Me₃SiCp)₂(N^{iBu}, N^{Me}-gnd);
the precursor being V(Me₃SiCp)₂(N^{nBu}, N^{Me}-gnd);
the precursor being V(Me₃SiCp)₂(N^{tBu}, N^{Me}-gnd);
the precursor being V(Me₃SiCp)₂(N^{sBu}, N^{Me}-gnd);
the precursor being V(Me₃SiCp)₂(N^{tAm}, N^{Me}-gnd);
the precursor being V(Me₃SiCp)₂(N^{TMS}, N^{Me}-gnd);
the precursor being V(Me₃SiCp)₂(N^{Et, tBu}, N^{Me-}gnd);
the precursor being V(Cp)(iPr₃Cp)(N^{Me}, N^{Me}-gnd);
the precursor being V(Cp)(Cp*)(N^{Me}, N^{Me}-gnd);
the precursor being V(Cp)(MeCp)(N^{Et}, N^{Me}-gnd);
the precursor being V(Cp)(EtCp)(N^{iPr}, N^{Me}-gnd);
the precursor being V(Cp)(iPrCp)(N^{nPr}, N^{Me}-gnd);
the precursor being V(Cp)(nPrCp)(N^{iBu}, N^{Me}-gnd);
the precursor being V(Cp)(iBuCp)(N^{nBu}, N^{Me}-gnd);
the precursor being V(Cp)(tBuCp)(N^{tBu}, N^{Me}-gnd);
the precursor being V(Cp)(tAmCp)(N^{sBu}, N^{Me}-gnd);
the precursor being V(Cp)₂(N^{iPr}, N^{Me, Et}-gnd);
the precursor being V(Cp)₂(N^{iPr}, N^{Et}-gnd);
the precursor being V(Cp)₂(N^{iPr}, N^{nPr}-gnd);
the precursor being V(Cp)₂(N^{iPr}, N^{iPr}-gnd);
the precursor being V(MeCp)₂(N^{iPr}, N^{Me, Et}-gnd);
the precursor being V(MeCp)₂(N^{iPr}, N^{Et}-gnd);
the precursor being V(MeCp)₂(N^{iPr}, N^{nPr}-gnd);
the precursor being V(MeCp)₂(N^{iPr}, N^{iPr}-gnd);
the precursor being V(EtCp)₂(N^{iPr}, N^{Me, Et}-gnd);
the precursor being V(EtCp)₂(N^{iPr}, N^{Et}-gnd);
the precursor being V(EtCp)₂(N^{iPr}, N^{nPr}-gnd);
the precursor being V(EtCp)₂(N^{iPr}, N^{iPr}-gnd);
the Vanadium-containing film forming composition comprising between approximately 95.0% w/w and approximately 100.0% w/w of the precursor;
the Vanadium-containing film forming composition comprising between approximately 5% w/w and approximately 50% w/w of the precursor;
the Vanadium-containing film forming composition comprising between approximately 0.0% w/w and approximately 5.0% w/w impurities;
the Vanadium-containing film forming composition comprising between approximately 0.0% w/w and approximately 2.0% w/w impurities;
the Vanadium-containing film forming composition comprising between approximately 0.0% w/w and approximately 1.0% w/w impurities;
the impurities including carbodiimides; formamidine; amidine; guanidine; alkylamines; dialkylamines; alkylimines; cyclopentadiene; dicyclopentadiene; THF; ether; pentane; cyclohexane; heptanes; benzene; toluene; chlorinated metal compounds; lithium, sodium, or potassium formamidinate; lithium, sodium, or potassium amidinate; lithium, sodium, or potassium guanidinate; and lithium, sodium, or potassium cyclopentadienyl;
the Vanadium-containing film forming composition comprising between approximately 0.0% w/w and approximately 2.0% w/w carbodiimide impurities;
the Vanadium-containing film forming composition comprising between approximately 0.0% w/w and approximately 2.0% w/w alkylamine impurities;
the Vanadium-containing film forming composition comprising between approximately 0.0% w/w and approximately 2.0% w/w alkylimine impurities;
the Vanadium-containing film forming composition comprising between approximately 0.0% w/w and approximately 2.0% w/w cyclopentadiene impurities;
the Vanadium-containing film forming composition comprising between approximately 0.0% w/w and approximately 2.0% w/w dicyclopentadiene impurities;
the Vanadium-containing film forming composition comprising between approximately 0.0% w/w and approximately 2.0% w/w THF impurities;
the Vanadium-containing film forming composition comprising between approximately 0.0% w/w and approximately 2.0% w/w ether impurities;
the Vanadium-containing film forming composition comprising between approximately 0.0% w/w and approximately 2.0% w/w pentane impurities;
the Vanadium-containing film forming composition comprising between approximately 0.0% w/w and approximately 2.0% w/w cyclohexane impurities;
the Vanadium-containing film forming composition comprising between approximately 0.0% w/w and approximately 2.0% w/w heptanes impurities;
the Vanadium-containing film forming composition comprising between approximately 0.0% w/w and approximately 2.0% w/w benzene impurities;
the Vanadium-containing film forming composition comprising between approximately 0.0% w/w and approximately 2.0% w/w toluene impurities;
the Vanadium-containing film forming composition comprising between approximately 0.0% w/w and approximately 2.0% w/w chlorinated metal compound impurities;
the Vanadium-containing film forming composition comprising between approximately 0.0% w/w and approximately 2.0% w/w lithium, sodium, or potassium formamidinate impurities;
the Vanadium-containing film forming composition comprising between approximately 0.0% w/w and approximately 2.0% w/w lithium, sodium, or potassium amidinate impurities;
the Vanadium-containing film forming composition comprising between approximately 0.0% w/w and approximately 2.0% w/w lithium, sodium, or potassium guanidinate impurities;
the Vanadium-containing film forming composition comprising between approximately 0.0% w/w and approximately 2.0% w/w lithum, sodium, or potassium cyclopentadienyl impurities;
the Vanadium-containing film forming composition comprising between approximately 0 ppbw and approximately 1 ppmw metal impurities;
the Vanadium-containing film forming composition comprising between approximately 0 ppbw and approximately 500 ppbw metal impurities;
the metal impurities including Aluminum (Al), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Indium (In), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti), Uranium (U), and Zinc (Zn);
the Vanadium-containing film forming composition comprising between approximately 0 ppbw and approximately 500 ppbw Al impurities;
the Vanadium-containing film forming composition comprising between approximately 0 ppbw and approximately 500 ppbw As impurities;
the Vanadium-containing film forming composition comprising between approximately 0 ppbw and approximately 500 ppbw Ba impurities;
the Vanadium-containing film forming composition comprising between approximately 0 ppbw and approximately 500 ppbw Be impurities;
the Vanadium-containing film forming composition comprising between approximately 0 ppbw and approximately 500 ppbw Bi impurities;
the Vanadium-containing film forming composition comprising between approximately 0 ppbw and approximately 500 ppbw Cd impurities;
the Vanadium-containing film forming composition comprising between approximately 0 ppbw and approximately 500 ppbw Ca impurities;
the Vanadium-containing film forming composition comprising between approximately 0 ppbw and approximately 500 ppbw Cr impurities;
the Vanadium-containing film forming composition comprising between approximately 0 ppbw and approximately 500 ppbw Co impurities;
the Vanadium-containing film forming composition comprising between approximately 0 ppbw and approximately 500 ppbw Cu impurities;
the Vanadium-containing film forming composition comprising between approximately 0 ppbw and approximately 500 ppbw Ga impurities;
the Vanadium-containing film forming composition comprising between approximately 0 ppbw and approximately 500 ppbw Ge impurities;
the Vanadium-containing film forming composition comprising between approximately 0 ppbw and approximately 500 ppbw Hf impurities;
the Vanadium-containing film forming composition comprising between approximately 0 ppbw and approximately 500 ppbw Zr impurities;
the Vanadium-containing film forming composition comprising between approximately 0 ppbw and approximately 500 ppbw In impurities;
the Vanadium-containing film forming composition comprising between approximately 0 ppbw and approximately 500 ppbw Fe impurities;
the Vanadium-containing film forming composition comprising between approximately 0 ppbw and approximately 500 ppbw Pb impurities;
the Vanadium-containing film forming composition comprising between approximately 0 ppbw and approximately 500 ppbw Li impurities;
the Vanadium-containing film forming composition comprising between approximately 0 ppbw and approximately 500 ppbw Mg impurities;
the Vanadium-containing film forming composition comprising between approximately 0 ppbw and approximately 500 ppbw Mn impurities;
the Vanadium-containing film forming composition comprising between approximately 0 ppbw and approximately 500 ppbw W impurities;
the Vanadium-containing film forming composition comprising between approximately 0 ppbw and approximately 500 ppbw Ni impurities;
the Vanadium-containing film forming composition comprising between approximately 0 ppbw and approximately 500 ppbw K impurities;
the Vanadium-containing film forming composition comprising between approximately 0 ppbw and approximately 500 ppbw Na impurities;
the Vanadium-containing film forming composition comprising between approximately 0 ppbw and approximately 500 ppbw Sr impurities;
the Vanadium-containing film forming composition comprising between approximately 0 ppbw and approximately 500 ppbw Th impurities;
the Vanadium-containing film forming composition comprising between approximately 0 ppbw and approximately 500 ppbw Sn impurities;
the Vanadium-containing film forming composition comprising between approximately 0 ppbw and approximately 500 ppbw Ti impurities;
the Vanadium-containing film forming composition comprising between approximately 0 ppbw and approximately 500 ppbw U impurities; and
the Vanadium-containing film forming composition comprising between approximately 0 ppbw and approximately 500 ppbw Zn impurities.

Also disclosed is a Ta-containing film forming composition delivery device comprising a canister having an inlet conduit and an outlet conduit and containing any of the Ta-containing film forming compositions disclosed above. The disclosed device may include one or more of the following aspects:
the Ta-containing film forming composition having a total concentration of metal contaminants of less than 10 ppmw;
an end of the inlet conduit end located above a surface of the Ta-containing film forming composition and an end of the outlet conduit located below the surface of the Ta-containing film forming composition;
an end of the inlet conduit end located below a surface of the Ta-containing film forming composition and an end of the outlet conduit located above the surface of the Ta-containing film forming composition; and
further comprising a diaphragm valve on the inlet and the outlet.

Also disclosed is a V-containing film forming composition delivery device comprising a canister having an inlet conduit and an outlet conduit and containing any of the V-containing film forming compositions disclosed above. The disclosed device may include one or more of the following aspects:
the V-containing film forming composition having a total concentration of metal contaminants of less than 10 ppmw;
an end of the inlet conduit end located above a surface of the V-containing film forming composition and an end of the outlet conduit located below the surface of the V-containing film forming composition;
an end of the inlet conduit end located below a surface of the V-containing film forming composition and an end of the outlet conduit located above the surface of the V-containing film forming composition; and
further comprising a diaphragm valve on the inlet and the outlet.

Also disclosed are processes for the deposition of Tantalum-containing films on one or more substrates. The vapor of the Tantalum-containing film forming composition(s) disclosed above is introduced into a reactor having a substrate disposed therein. At least part of the precursor is deposited onto the at least one substrate to form the Tantalum-containing film.

Also disclosed are processes for the deposition of Vanadium-containing films on one or more substrates. The vapor of the Vanadium-containing film forming composition(s) disclosed above is introduced into a reactor having a substrate disposed therein. At least part of the precursor is deposited onto the at least one substrate to form the Vanadium-containing film.

Either of the disclosed processes may further include one or more of the following aspects:
introducing at least one reactant into the reactor;
the reactant being selected from the group consisting of H₂, NH₃, SiH₄, Si₂H₆, Si₃H₈, SiH₂Me₂, SiH₂Et₂, N(SiH₃)₃, hydrogen radicals thereof; and mixtures thereof;
the reactant being selected from the group consisting of: O₂, O₃, H₂O, NO, N₂O, oxygen radicals thereof; and mixtures thereof;
the Tantalum-containing film forming composition and the reactant being introduced into the reactor substantially simultaneously;
the Vanadium-containing film forming composition and the reactant being introduced into the reactor substantially simultaneously;
the reactor being configured for chemical vapor deposition;
the reactor being configured for plasma enhanced chemical vapor deposition;
the Tantalum-containing film forming composition and the reactant being introduced into the chamber sequentially;
the Vanadium-containing film forming composition and the reactant being introduced into the chamber sequentially;
the reactor being configured for atomic layer deposition;
the reactor being configured for spatial atomic layer deposition; and
the reactor being configured for plasma enhanced atomic layer deposition.

### BRIEF DESCRIPTION OF THE FIGURES

For a further understanding of the nature and objects of the present invention, reference should be made to the following detailed description, taken in conjunction with the accompanying figure wherein:

FIG. 1 is a side view of one embodiment of the Ta-containing film forming composition or V-containing film forming composition delivery device disclosed herein; and

FIG. 2 is a side view of a second embodiment of the Ta-containing film forming composition or V-containing film forming composition delivery device disclosed herein.

### DESCRIPTION OF PREFERRED EMBODIMENTS

Disclosed are Tantalum-containing film forming compositions comprising precursors having the formula:

Ta(R₅Cp)₂(L)

wherein each R is independently H, an alkyl group, or R′₃Si, with each R′ independently being H or an alkyl group; and L is selected from the group consisting of formamidinates (N^{R, R′}-fmd or N^{R}-fmd when R═R′), amidinates (N^{R, R′} R″-amd or N^{R} R^{″}-amd when R═R′), and guanidinates (N^{R, R′} , N^{R″, R″′}-gnd or N^{R}, N^{R}″-gnd when R═R′ and R″═R′″).

The precursor may have the formula Ta(R₅Cp)₂(N^{R, R′}-fmd):

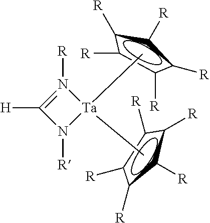

wherein each R and R′ is independently H, a C1 to C6 alkyl group, or SiR″₃, with each R″ independently being H or a C1 to C6 alkyl group. Preferably, each R and R′ is independently H, Me, Et, nPr, iPr, tBu, sBu, iBu, nBu, tAmyl, SiMe₃, SiMe₂H, or SiH₂Me. When R═R′ on the fmd ligand, the formula is Ta(R₅Cp)₂(N^{R}-fmd).

Exemplary precursors include Ta(Cp)₂(N^{Me}-fmd), Ta(Cp)₂(N^{Et}-fmd), Ta(Cp)₂(N^{iPr}-fmd), Ta(Cp)₂(N^{nPr}-fmd), Ta(Cp)₂(N^{iBu}-fmd), Ta(Cp)₂(N^{nBu}-fmd), Ta(Cp)₂(N^{tBu}-fmd), Ta(Cp)₂(N^{sBu}-fmd), Ta(Cp)₂(N^{tAm}-fmd), Ta(Cp)₂(N^{TMS}-fmd), Ta(MeCp)₂(N^{Me}-fmd), Ta(MeCp)₂(N^{Et}-fmd), Ta(MeCp)₂(N^{iPr}-fmd), Ta(MeCp)₂(N^{nPr}-fmd), Ta(MeCp)₂(N^{iBu}-fmd), Ta(MeCp)₂(N^{nBu}-fmd), Ta(MeCp)₂(N^{tBu}-fmd), Ta(MeCp)₂(N^{sBu}-fmd), Ta(MeCp)₂(N^{tAm}-fmd), Ta(MeCp)₂(N^{TMS}-fmd), Ta(EtCp)₂(N^{Me}-fmd), Ta(EtCp)₂(N^{Et}-fmd), Ta(EtCp)₂(N^{iPr}-fmd), Ta(EtCp)₂(N^{nPr}-fmd), Ta(EtCp)₂(N^{iBu}-fmd), Ta(EtCp)₂(N^{nBu}-fmd), Ta(EtCp)₂(N^{tBu}-fmd), Ta(EtCp)₂(N^{sBu}-fmd), Ta(EtCp)₂(N^{tAm}-fmd), Ta(EtCp)₂(N^{TMS}-fmd), Ta(iPrCp)₂(N^{Me}-fmd), Ta(iPrCp)₂(N^{Et}-fmd), Ta(iPrCp)₂(N^{iPr}-fmd), Ta(iPrCp)₂(N^{nPr}-fmd), Ta(iPrCp)₂(N^{iBu}-fmd), Ta(iPrCp)₂(N^{nBu}-fmd), Ta(iPrCp)₂(N^{tBu}-fmd), Ta(iPrCp)₂(N^{sBu}-fmd), Ta(iPrCp)₂(N^{tAm}-fmd), Ta(iPrCp)₂(N^{TMS}-fmd), Ta(tBuCp)₂(N^{Me}-fmd), Ta(tBuCp)₂(N^{Et}-fmd), Ta(tBuCp)₂(N^{iPr}-fmd), Ta(tBuCp)₂(N^{nPr}-fmd), Ta(tBuCp)₂(N^{iBu}-fmd), Ta(tBuCp)₂(N^{nBu}-fmd), Ta(tBuCp)₂(N^{tBu}-fmd), Ta(tBuCp)₂(N^{sBu}-fmd), Ta(tBuCp)₂(N^{tAm}-fmd), Ta(tBuCp)₂(N^{TMS}-fmd), Ta(iPr₃Cp)₂(N^{Me}-fmd), Ta(iPr₃Cp)₂(N^{Et}-fmd), Ta(iPr₃Cp)₂(N^{iPr}-fmd), Ta(iPr₃Cp)₂(N^{nPr}-fmd), Ta(iPr₃Cp)₂(N^{iBu}-fmd), Ta(iPr₃Cp)₂(N^{nBu}-fmd), Ta(iPr₃Cp)₂(N^{tBu}-fmd), Ta(iPr₃Cp)₂(N^{sBu}-fmd), Ta(iPr₃Cp)₂(N^{tAm}-fmd), Ta(iPr₃Cp)₂(N^{TMS}-fmd), Ta(Cp*)₂(N^{Me}-fmd), Ta(Cp*)₂(N^{Et}-fmd), Ta(Cp*)₂(N^{iPr}-fmd), Ta(Cp*)₂(N^{nPr}-fmd), Ta(Cp*)₂(N^{iBu}-fmd), Ta(Cp*)₂(^{nBu}-fmd), Ta(CP*)₂(^{tBu}-fmd), Ta(Cp*)₂(N^{sBu}-fmd), Ta(Cp*)₂(N^{tAm}-fmd), Ta(Cp*)₂(N^{TMS}-fmd), Ta(Me₃SiCp)₂(N^{Me}-fmd), Ta(Me₃SiCp)₂(N^{Et}-fmd), Ta(Me₃SiCp)₂(N^{iPr}-fmd), Ta(Me₃SiCp)₂(N^{nPr}-fmd), Ta(Me₃SiCp)₂(N^{iBu}-fmd), Ta(Me₃SiCp)₂(N^{nBu}-fmd), Ta(Me₃SiCp)₂(N^{tBu}-fmd), Ta(Me₃SiCp)₂(N^{sBu}-fmd), Ta(Me₃SiCp)₂(N^{tAm}-fmd), Ta(Me₃SiCp)₂(N^{TMS}-fmd), Ta(Cp)(Cp*)(N^{Me}-fmd), Ta(Cp)(iPr₃Cp)(N^{Me}-fmd), Ta(Cp)(MeCp)(N^{Et}-fmd), Ta(Cp)(EtCp)(N^{iPr}-fmd), Ta(Cp)(iPrCp)(N^{nPr}-fmd), Ta(Cp)(nPrCp)(N^{iBu}-fmd), Ta(Cp)(iBuCp)(N^{nBu}-fmd), Ta(Cp)(tBuCp)(N^{tBu}-fmd), Ta(Cp)(tAmCp)(N^{sBu}-fmd), Ta(Cp)₂(N^{Et, tBu}-fmd), Ta(MeCp)₂(N^{Et, tBu}-fmd) or Ta(EtCp)₂(N^{Et, tBu}-fmd).

These precursors may be synthesized by reacting Ta(R₅Cp)₂X₂ with two (2) equivalents of Z(N^{R, R′}-fmd) wherein X is an halogen selected from the group consisting of F, Cl, Br and I; Z is an alkali metal selected from the group consisting of Li, Na and K; and each R and R′ is independently H, Me, Et, nPr, iPr, tBu, sBu, iBu, nBu, tAmyl, SiMe₃, SiMe₂H, or SiH₂Me. Ta(R₅Cp)₂X₂ may be prepared as described in J. C. S. Dalton 1980, 180-186. Z(NI^{R, R′}-fmd) may be prepared by reaction of an alkyl alkali-metal, such as n-Butyl Lithium (nBuLi), with the corresponding formamidine molecule. The formamidine molecule may be prepared according to the procedure described in Organometallics 2004, 23, 3512-3520. The additions of the reactants may be done at low temperature, the temperature being below −50° C. The reaction may be done in a polar solvent, such as THF or diethylether. The precursor may be separated from alkali salts by extraction with a non polar solvent, such as pentane, hexane, cyclohexane, heptanes, benzene and toluene. The resulting Tantalum-containing film forming composition may be purified by vacuum sublimation, vacuum distillation, or by recrystallisation in a suitable solvent, such as THF, diethylether, pentane, hexane, cyclohexane, heptanes, benzene, toluene, or mixtures thereof.

The precursor may have the formula Ta(R₅Cp)₂(N^{R}′^{R}′ R″-amd):

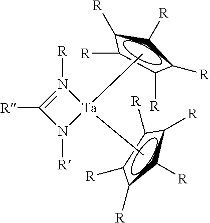

wherein each R, R′, and R″ is independently H, a C1 to C6 alkyl group, or SiR′″₃, with each R′″ independently being H or a C1 to C6 alkyl group. Preferably, each R, R′, or R″ is independently H, Me, Et, nPr, iPr, tBu, sBu, iBu, nBu, tAmyl, SiMe₃, SiMe₂H, or SiH₂Me. When R═R′ on the amidinate ligand, the formula is Ta(R₅Cp)₂(N^{R} R″-amd).

Exemplary Tantalum-containing film forming precursors include Ta(Cp)₂(N^{Me} Me-amd), Ta(Cp)₂(N^{Et} Me-amd), Ta(Cp)₂(N^{iPr} Me-amd), Ta(Cp)₂(N^{nPr} Me-amd), Ta(Cp)₂(N^{iBu} Me-amd), Ta(Cp)₂(N^{nBu} Me-amd), Ta(Cp)₂(N^{tBu} Me-amd), Ta(Cp)₂(N^{sBu} Me-amd), Ta(Cp)₂(N^{tAm} Me-amd), Ta(Cp)₂(N^{TMS} Me-amd), Ta(MeCp)₂(N^{Me} Me-amd), Ta(MeCp)₂(N^{Et} Me-amd), Ta(MeCp)₂(N^{iPr} Me-amd), Ta(MeCp)₂(N^{nPr} Me-amd), Ta(MeCp)₂(N^{iBu} Me-amd), Ta(MeCp)₂(N^{nBu} Me-amd), Ta(MeCp)₂(N^{tBu} Me-amd), Ta(MeCp)₂(N^{sBu} Me-amd), Ta(MeCp)₂(N^{tAm} Me-amd), Ta(MeCp)₂(N^{TMS} Me-amd), Ta(EtCp)₂(N^{Me} Me-amd), Ta(EtCp)₂(N^{Et} Me-amd), Ta(EtCp)₂(N^{iPr} Me-amd), Ta(EtCp)₂(N^{nPr} Me-amd), Ta(EtCp)₂(N^{iBu} Me-amd), Ta(EtCp)₂(N^{nBu} Me-amd), Ta(EtCp)₂(N^{tBu} Me-amd), Ta(EtCp)₂(N^{sBu} Me-amd), Ta(EtCp)₂(N^{tAm} Me-amd), Ta(EtCp)₂(N^{TMS} Me-amd), Ta(iPrCp)₂(N^{Me} Me-amd), Ta(iPrCp)₂(N^{Et} Me-amd), Ta(iPrCp)₂(N^{iPr} Me-amd), Ta(iPrCp)₂(N^{nPr} Me-amd), Ta(iPrCp)₂(N^{iBu} Me-amd), Ta(iPrCp)₂(N^{nBu} Me-amd), Ta(iPrCp)₂(N^{tBu} Me-amd), Ta(iPrCp)₂(N^{sBu} Me-amd), Ta(iPrCp)₂(N^{tAm} Me-amd), Ta(iPrCp)₂(N^{TMS} Me-amd), Ta(tBuCp)₂(N^{Me} Me-amd), Ta(tBuCp)₂(N^{Et} Me-amd), Ta(tBuCp)₂(N^{iPr} Me-amd), Ta(tBuCp)₂(N^{nPr} Me-amd), Ta(tBuCp)₂(N^{iBu} Me-amd), Ta(tBuCp)₂(N^{nBu} Me-amd), Ta(tBuCp)₂(N^{tBu} Me-amd), Ta(tBuCp)₂(N^{sBu} Me-amd), Ta(tBuCp)₂(N^{tAm} Me-amd), Ta(tBuCp)₂(N^{TMS} Me-amd), Ta(iPr₃Cp)₂(N^{Me} Me-amd), Ta(iPr₃Cp)₂(N^{Et} Me-amd), Ta(iPr₃Cp)₂(N^{iPr} Me-amd), Ta(iPr₃Cp)₂(N^{nPr} Me-amd), Ta(iPr₃Cp)₂(N^{iBu} Me-amd), Ta(iPr₃Cp)₂(N^{nBu} Me-amd), Ta(iPr₃Cp)₂(N^{tBu} Me-amd), Ta(iPr₃Cp)₂(N^{sBu} Me-amd), Ta(iPr₃Cp)₂(N^{tAm} Me-amd), Ta(iPr₃Cp)₂(N^{TMS} Me-amd), Ta(Cp*)₂(N^{Me} Me-amd), Ta(Cp*)₂(N^{Et} Me-amd), Ta(Cp*)₂(N^{iPr} Me-amd), Ta(Cp*)₂(N^{nPr} Me-amd), Ta(Cp*)₂(N^{iBu} Me-amd), Ta(Cp*)₂(^{nBu} Me-amd), Ta(Cp*)₂(^{tBu} Me-amd), Ta(CP*)₂(N^{sBu} Me-amd), Ta(Cp*)₂(N^{tAm} Me-amd), Ta(Cp*)₂(N^{TMS} Me-amd), Ta(Me₃SiCp)₂(N^{Me} Me-amd), Ta(Me₃SiCp)₂(N^{Et} Me-amd), Ta(Me₃SiCp)₂(N^{iPr} Me-amd), Ta(Me₃SiCp)₂(N^{nPr} Me-amd), Ta(Me₃SiCp)₂(N^{iBu} Me-amd), Ta(Me₃SiCp)₂(N^{nBu} Me-amd), Ta(Me₃SiCp)₂(N^{tBu} Me-amd), Ta(Me₃SiCp)₂(N^{sBu} Me-amd), Ta(Me₃SiCp)₂(N^{tAm} Me-amd), Ta(Me₃SiCp)₂(N^{TMS} Me-amd), Ta(Cp)(Cp*)(N^{Me} Me-amd), Ta(Cp)(iPr₃Cp)(N^{Me} Me-amd), Ta(Cp)(MeCp)(N^{Et} Me-amd), Ta(Cp)(EtCp)(N^{iPr} Me-amd), Ta(Cp)(iPrCp)(N^{nPr} Me-amd), Ta(Cp)(nPrCp)(N^{iBu} Me-amd), Ta(Cp)(iBuCp)(N^{nBu} Me-amd), Ta(Cp)(tBuCp)(N^{tBu} Me-amd), Ta(Cp)(tAmCp)(N^{sBu} Me-amd), Ta(Cp)₂(N^{iPr} Et-amd), Ta(Cp)₂(N^{iPr} nPr-amd), Ta(Cp)₂(N^{iPr} iPr-amd), Ta(Cp)₂(N^{iPr} tBu-amd), Ta(Cp)₂(N^{iPr} nBu-amd), Ta(Cp)₂(N^{iPr} iBu-amd), Ta(Cp)₂(N^{iPr} sBu-amd), Ta(MeCp)₂(N^{iPr} Et-amd), Ta(MeCp)₂(N^{iPr} nPr-amd), Ta(MeCp)₂(N^{iPr} iPr-amd), Ta(MeCp)₂(N^{iPr} tBu-amd), Ta(MeCp)₂(N^{iPr} nBu-amd), Ta(MeCp)₂(N^{iPr} iBu-amd), Ta(MeCp)₂(N^{iPr} sBu-amd), Ta(EtCp)₂(N^{iPr} Et-amd), Ta(EtCp)₂(N^{iPr} nPr-amd), Ta(EtCp)₂(N^{iPr} iPr-amd), Ta(EtCp)₂(N^{iPr} tBu-amd), Ta(EtCp)₂(N^{iPr} nBu-amd), Ta(EtCp)₂(N^{iPr} iBu-amd) or Ta(EtCp)₂(N^{iP}, sBu-amd). These precursors may be synthesized by reacting Ta(R₅Cp)₂X₂ with two (2) equivalents of Z(N^{R, R′} R″-amd) wherein X is an halogen selected from the group consisting of F, Cl, Br and I; Z is an alkali metal selected from the group consisting of Li, Na and K; and each R, R′, and R″ is independently H, Me, Et, nPr, iPr, tBu, sBu, iBu, nBu, tAmyl, SiMe₃, SiMe₂H, or SiH₂Me. Ta(R₅Cp)₂X₂ is prepared as described in J.C.S. Dalton 1980, 180-186. Z(N^{R, R′} R″-amd) may be prepared as described in Organometallics 1997, 16, 5183-5194. The additions of the reactants may be done at low temperature, the temperature being below −50° C. The reaction may be done in a polar solvent, such as THF and diethylether. The precursor may be separated from alkali salts by extraction with a non polar solvent, such as pentane, hexane, cyclohexane, heptanes, benzene and toluene. The resulting Tantalum-containing film forming compositions may be purified by vacuum sublimation, vacuum distillation, or by recrystallisation in a suitable solvent, such as THF, diethylether, pentane, hexane, cyclohexane, heptanes, benzene, toluene, or mixtures thereof.

The precursor may have the formula Ta(R₅Cp)₂(N^{R, R′}, N^{R″, R′″}-gnd):

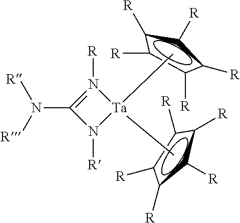

wherein each R, R′, R″ and R′″ is independently H, a C1 to C6 alkyl group, or SiR″″₃, with each R″″ being H or a C1 to C6 alkyl group. Preferably, each R, R′, or R″ is independently H, Me, Et, nPr, iPr, tBu, sBu, iBu, nBu, tAmyl, SiMe₃, SiMe₂H, or SiH₂Me. When R═R′ and R″═R″′ on the guanidinate ligand, the formula is Ta(R₅Cp)₂(N^{R}, N^{R″}-gnd).

Exemplary precursors include Ta(Cp)₂(N^{Me}, N^{Me}-gnd), Ta(Cp)₂(N^{Et}, N^{Me}-gnd), Ta(Cp)₂(N^{iPr}, N^{Me}-gnd), Ta(Cp)₂(N^{nPr}, N^{Me}-gnd), Ta(Cp)₂(N^{iBu}, N^{Me}-gnd), Ta(Cp)₂(N^{nBu}, N^{Me}-gnd), Ta(Cp)₂(N^{tBu}, N^{Me}-gnd), Ta(Cp)₂(N^{sBu}, N^{Me}-gnd), Ta(Cp)₂(N^{tAm}, N^{Me}-gnd), Ta(Cp)₂(N^{TMS}, N^{Me}-gnd), Ta(MeCp)₂(N^{Me}, N^{Me}-gnd), Ta(MeCp)₂(N^{Et}, N^{Me}-gnd), Ta(MeCp)₂(N^{iPr}, N^{Me}-gnd), Ta(MeCp)₂(N^{nPr}, N^{Me}-gnd), Ta(MeCp)₂(N^{iBu}, N^{Me}-gnd), Ta(MeCp)₂(N^{nBu}, N^{Me}-gnd), Ta(MeCp)₂(N^{tBu}, N^{Me}-gnd), Ta(MeCp)₂(N^{sBu}, N^{Me}-gnd), Ta(MeCp)₂(N^{tAm}, N^{Me}-gnd), Ta(MeCp)₂(N^{TMS}, N^{Me}-gnd), Ta(EtCp)₂(N^{Me}, N^{Me}-gnd), Ta(EtCp)₂(N^{Et}, N^{Me}-gnd), Ta(EtCp)₂(N^{iPr}, N^{Me}-gnd), Ta(EtCp)₂(N^{nPr}, N^{Me}-gnd), Ta(EtCp)₂(N^{iBu}, N^{Me}-gnd), Ta(EtCp)₂(N^{nBu}, N^{Me}-gnd), Ta(EtCp)₂(N^{tBu}, N^{Me}-gnd), Ta(EtCp)₂(N^{sBu}, N^{Me}-gnd), Ta(EtCp)₂(N^{tAm}, N^{Me}-gnd), Ta(EtCp)₂(N^{TMS}, N^{Me}-gnd), Ta(iPrCp)₂(N^{Me}, N^{Me}-gnd), Ta(iPrCp)₂(N^{Et}, N^{Me}-gnd), Ta(iPrCp)₂(N^{iPr}, N^{Me}-gnd), Ta(iPrCp)₂(N^{nPr}, N^{Me}-gnd), Ta(iPrCp)₂(N^{iBu}, N^{Me}-gnd), Ta(iPrCp)₂(N^{nBu}, N^{Me}-gnd), Ta(iPrCp)₂(N^{tBu}, N^{Me}-gnd), Ta(iPrCp)₂(N^{sBu}, N^{Me}-gnd), Ta(iPrCp)₂(N^{tAm}, N^{Me}-gnd), Ta(iPrCp)₂(N^{TMS}, N^{Me}-gnd), Ta(tBuCp)₂(N^{Me}, N^{Me}-gnd), Ta(tBuCp)₂(N^{Et}, N^{Me}-gnd), Ta(tBuCp)₂(N^{iPr}, N^{Me}-gnd), Ta(tBuCp)₂(N^{nPr}, N^{Me}-gnd), Ta(tBuCp)₂(N^{iBu}, N^{Me}-gnd), Ta(tBuCp)₂(N^{nBu}, N^{Me}-gnd), Ta(tBuCp)₂(N^{tBu}, N^{Me}-gnd), Ta(tBuCp)₂(N^{sBu}, N^{Me}-gnd), Ta(tBuCp)₂(N^{tAm}, N^{Me}-gnd), Ta(tBuCp)₂(N^{Tms}, N^{Me}-gnd), Ta(iPr₃Cp)₂(N^{Me}, N^{Me}-gnd), Ta(iPr₃Cp)₂(N^{Et}, N^{Me}-gnd), Ta(iPr₃Cp)₂(N^{iPr}, N^{Me}-gnd), Ta(iPr₃Cp)₂(N^{nPr}, N^{Me}-gnd), Ta(iPr₃Cp)₂(N^{iBu}, N^{Me}-gnd), Ta(iPr₃Cp)₂(N^{nBu}, N^{Me}-gnd), Ta(iPr₃Cp)₂(N^{tBu}, N^{Me}-gnd), Ta(iPr₃Cp)₂(N^{sBu}, N^{Me}-gnd), Ta(iPr₃Cp)₂(N^{tAm}, N^{me}-gnd), Ta(iPr₃Cp)₂(N^{TMS}, N^{Me}-gnd), Ta(Cp*)₂(N^{Me}, N^{Me}-gnd), Ta(Cp*)₂(N^{Et}, N^{Me}-gnd), Ta(Cp*)₂(N^{iPr}, N^{Me}-gnd), Ta(Cp*)₂(N^{nPr}, N^{Me}-gnd), Ta(Cp*)₂(N^{iBu}, N^{Me}-gnd), Ta(Cp*)₂(^{nBu}, N^{Me}-gnd), Ta(Cp*)₂(^{tBu}, N^{Me}-gnd), Ta(Cp*)₂(N^{sBu}, N^{Me}-gnd), Ta(Cp*)₂(N^{tAm}, N^{Me}-gnd), Ta(Cp*)₂(N^{TMS}, N^{Me}-gnd), Ta(^{Me}₃SiCp)₂(N^{Me}, N^{Me}-gnd), Ta(^{Me}₃SiCp)₂(N^{Et}, N^{Me}-gnd), Ta(^{Me}₃SiCp)₂(N^{iPr}, N^{Me}-gnd), Ta(^{Me}₃SiCp)₂(N^{nPr}, N^{Me}-gnd), Ta(^{Me}₃SiCp)₂(N^{iBu}, N^{Me}-gnd), Ta(^{Me}₃SiCp)₂(N^{nBu}, N^{Me}-gnd), Ta(^{Me}₃SiCp)₂(N^{tBu}, N^{Me}-gnd), Ta(^{Me}₃SiCp)₂(N^{sBu}, N^{Me}-gnd), Ta(^{Me}₃SiCp)₂(N^{tAm}, N^{Me}-gnd), Ta(^{Me}₃SiCp)₂(N^{TMS}, N^{Me}-gnd), Ta(Cp)(Cp*)(N^{Me}, N^{Me}-gnd), Ta(Cp)(iPr₃Cp)(N^{Me}, N^{Me}-gnd), Ta(Cp)(MeCp)(N^{Et}, N^{Me}-gnd), Ta(Cp)(EtCp)(N^{iPr}, N^{Me}-gnd), Ta(Cp)(iPrCp)(N^{nPr}, N^{Me}-gnd), Ta(Cp)(nPrCp)(N^{iBu}, N^{Me}-gnd), Ta(Cp)(iBuCp)(N^{nBu}, N^{Me}-gnd), Ta(Cp)(tBuCp)(N^{tBu}, N^{Me}-gnd), Ta(Cp)(tAmCp)(N^{sBu}, N^{Me}-gnd), Ta(Cp)₂(N^{iPr}, N^{Me, Et}-gnd), Ta(Cp)₂(N^{iPr}, N^{Et}-gnd), Ta(Cp)₂(N^{iPr}, N^{nPr}-gnd), Ta(Cp)₂(N^{iPr}, N^{iPr}-gnd), Ta(MeCp)₂(N^{iPr}, N^{Me, Et}-gnd), Ta(MeCp)₂(N^{iPr}, N^{Et}-gnd), Ta(MeCp)₂(N^{iPr}, N^{nPr}-gnd), Ta(MeCp)₂(N^{iPr}, N^{iPr}-gnd), Ta(EtCp)₂(N^{iPr}, N^{Me, Et}-gnd), Ta(EtCp)₂(N^{iPr}, N^{Et}-gnd), Ta(EtCp)₂(N^{iPr}, N^{nPr}-gnd), or Ta(EtCp)₂(N^{iPr}, N^{iPr}-gnd).

These precursors may be synthesized by reacting Ta(R₅Cp)₂X₂ with two (2) equivalents of Z(N^{R, R′}, N^{R″, R′″}-gnd) wherein X is an halogen selected from the group consisting of F, Cl, Br and I; Z is an alkali metal selected from the group consisting of Li, Na and K; and each R, R′, R″, and R′″ is independently H, Me, Et, nPr, iPr, tBu, sBu, iBu, nBu, tAmyl, SiMe₃, SiMe₂H, or SiH₂Me. Ta(R₅Cp)₂X₂ is prepared as described in J.C.S. Dalton 1980, 180-186. Z(N^{R, R′}, N^{R″, R′″}-gnd) may be prepared as described in Organometallics 2008, 27, 1596-1604. The additions of the reactants may be done at low temperature, the temperature being below −50° C. The reaction may be done in a polar solvent, such as THF and diethylether. The precursor may be separated from alkali salts by extraction with a non polar solvent, such as pentane, hexane, cyclohexane, heptanes, benzene and toluene. The resulting Tantalum-containing film forming composition may be purified by vacuum sublimation, vacuum distillation, or by recrystallisation in a suitable solvent, such as THF, diethylether, pentane, hexane, cyclohexane, heptanes, benzene, toluene, or mixtures thereof.

Purity of the disclosed Tantalum-containing film forming compositions is preferably higher than 95% w/w (i.e., 95.0% w/w to 100.0% w/w), preferably greater than 98% w/w (98.0% w/w to 100.0% w/w), and more preferably greater than 99% w/w (99.0% w/w to 100.0% w/w). One of ordinary skill in the art will recognize that the purity may be determined by H NMR or gas or liquid chromatography with mass spectrometry. The disclosed Tantalum-containing film forming compositions may contain any of the following impurities: carbodiimides; alkylamines; dialkylamines; alkylimines; cyclopentadiene; dicyclopentadiene; THF; ether; pentane; cyclohexane; heptanes; benzene; toluene; chlorinated metal compounds; lithium, sodium or potassium formamidinate; lithium, sodium or potassium amidinate; lithium, sodium or potassium guanidinate; or lithium, sodium or potassium cyclopentadienyl. The total quantity of these impurities is below 5% w/w (i.e. 0.0% w/w to 5.0% w/w), preferably below 2% w/w (i.e., 0.0% w/w to 2.0% w/w), and even more preferably below 1% w/w (i.e., 0.0% w/w to 1.0% w/w). The composition may be purified by recrystallisation, sublimation, distillation, and/or passing the gas or liquid through a suitable adsorbent, such as a 4A molecular sieve.

Purification of the disclosed Tantalum-containing film forming composition may also result in metal impurities at the 0 ppbw to 1 ppmw, preferably 0-500 ppbw (part per billion weight) level. These metal impurities include, but are not limited to, Aluminum (Al), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Indium (In), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti),

Uranium (U), Vanadium (V) and Zinc (Zn).

Also disclosed are Vanadium-containing film forming compositions comprising precursors having the formula:

V(R₅Cp)₂(L)

wherein each R is independently H, an alkyl group, or R′₃Si, with each R′ independently being H or an alkyl group; and L is selected from the group consisting of formamidinates (N^{R, R′}-fmd or N^{R}-fmd when R═R′), amidinates (N^{R, R′} R″-amd or N^{R} R″-amd when R═R′), and guanidinates (N^{R, R′}, N^{R″, R′″}-gnd or N^{R}, N^{R″}-gnd when R═R′ and R″═R′″).

The precursor may have the formula V(R₅Cp)₂(N^{R, R′}-fmd):

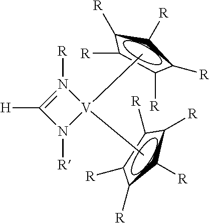

wherein each R and R′ is independently H, a C1 to C6 alkyl group, or SiR″₃, with each R″ independently being H or a C1 to C6 alkyl group. Preferably, each R and R′ is independently H, Me, Et, nPr, iPr, tBu, sBu, iBu, nBu, tAmyl, SiMe₃, SiMe₂H, or SiH₂Me. When R═R′ on the fmd ligand, the formula is V(R₅Cp)₂(N^{R}-fmd).

Exemplary precursors include V(Cp)₂(N^{Me}-fmd), V(Cp)₂(N^{Et}-fmd), V(Cp)₂(N^{iPr}-fmd), V(Cp)₂(N^{nPr}-fmd), V(Cp)₂(N^{iBu}-fmd), V(Cp)₂(N^{nBu}-fmd), V(Cp)₂(N^{tBu}-fmd), V(Cp)₂(N^{sBu}-fmd), V(Cp)₂(N^{tAm}-fmd), V(Cp)₂(N^{TMS}-fmd), V(MeCp)₂(N^{Me}-fmd), V(MeCp)₂(N^{Et}-fmd), V(MeCp)₂(N^{iPr}-fmd), V(MeCp)₂(N^{nPr}-fmd), V(MeCp)₂(N^{iBu}-fmd), V(MeCp)₂(N^{nBu}-fmd), V(MeCp)₂(N^{tBu}-fmd), V(MeCp)₂(N^{sBu}-fmd), V(MeCp)₂(N^{tAm}-fmd), V(MeCp)₂(N^{TMS}-fmd), V(EtCp)₂(N^{Me}-fmd), V(EtCp)₂(N^{Et}-fmd), V(EtCp)₂(N^{iPr}-fmd), V(EtCp)₂(N^{nPr}-fmd), V(EtCp)₂(N^{iBu}-fmd), V(EtCp)₂(N^{nBu}-fmd), V(EtCp)₂(N^{tBu}-fmd), V(EtCp)₂(N^{sBu}-fmd), V(EtCp)₂(N^{tAm}-fmd), V(EtCp)₂(N^{TMS}-fmd), V(iPrCp)₂(N^{Me}-fmd), V(iPrCp)₂(N^{Et}-fmd), V(iPrCp)₂(N^{iPr}-fmd), V(iPrCp)₂(N^{nPr}-fmd), V(iPrCp)₂(N^{iBu}-fmd), V(iPrCp)₂(N^{nBu}-fmd), V(iPrCp)₂(N^{tBu}-fmd), V(iPrCp)₂(N^{sBu}-fmd), V(iPrCp)₂(N^{tAm}-fmd), V(iPrCp)₂(N^{TMS}-fmd), V(tBuCp)₂(N^{Me}-fmd), V(tBuCp)₂(N^{Et}-fmd), V(tBuCp)₂(N^{iPr}-fmd), V(tBuCp)₂(N^{nPr}-fmd), V(tBuCp)₂(N^{iBu}-fmd), V(tBuCp)₂(N^{nBu}-fmd), V(tBuCp)₂(N^{tBu}-fmd), V(tBuCp)₂(N^{sBu}-fmd), V(tBuCp)₂(N^{tAm}-fmd), V(tBuCp)₂(N^{TMS}-fmd), V(iPr₃Cp)₂(N^{Me}-fmd), V(iPr₃Cp)₂(N^{Et}-fmd), V(iPr₃Cp)₂(N^{iPr}-fmd), V(iPr₃Cp)₂(N^{nPr}-fmd), V(iPr₃Cp)₂(N^{iBu}-fmd), V(iPr₃Cp)₂(N^{nBu}-fmd), V(iPr₃Cp)₂(N^{tBu}-fmd), V(iPr₃Cp)₂(N^{sBu}-fmd), V(iPr₃CO₂(N^{tAm}-fmd), V(iPr₃Cp)₂(N^{TMS}-fmd), V(Cp*)₂(N^{Me}-fmd), V(Cp*)₂(N^{Et}-fmd), V(Cp*)₂(N^{iPr}-fmd), V(Cp*)₂(N^{nPr}-fmd), V(Cp*)₂(N ^{iBu}-fmd), V(Cp*)₂(^{nBu}-fmd), V(Cp*)²(^{tBu}-fmd), V(Cp*)₂(N^{sBu}-fmd), V(Cp*)₂(N^{tAm}-fmd), V(Cp*)₂(N^{TMS}-fmd), V(Me₃SiCp)₂(N^{Me}-fmd), V(Me₃SiCp)₂(N^{Et}-fmd), V(Me₃SiCp)₂(N^{iPr}-fmd), V(Me₃SiCp)₂(N^{nPr}-fmd), V(Me₃SiCp)₂(N^{iBu}-fmd), V(Me₃SiCp)₂(N^{nBu}-fmd), V(Me₃SiCp)₂(N^{tBu}-fmd), V(Me₃SiCp)₂(N^{sBu}-fmd), V(Me₃SiCp)₂(N^{tAm}-fmd), V(Me₃SiCp)₂(N^{TMS}-fmd), V(Cp)(Cp*)(N^{Me}-fmd), V(Cp)(iPr₃Cp)(N^{Me}-fmd), V(Cp)(MeCp)(N^{Et}-fmd), V(Cp)(EtCp)(N^{iPr}-fmd), V(Cp)(iPrCp)(N^{nPr}-fmd), V(Cp)(nPrCp)(N^{iBu}-fmd), V(Cp)(iBuCp)(N^{nBu}-fmd), V(Cp)(tBuCp)(N^{tBu}-fmd), V(Cp)(tAmCp)(N^{sBu}-fmd), V(Cp)₂(N^{Et, tBu}-fmd), V(MeCp)₂(N^{Et, tBu}-fmd) or V(EtCp)₂(N^{Et, tBu}-fmd).

These precursors may be synthesized by reacting V(R₅Cp)₂X₂ with two (2) equivalents of Z(N^{R, R′}-fmd) wherein X is an halogen selected from the group consisting of F, Cl, Br and I; Z is an alkali metal selected from the group consisting of Li, Na and K; and each R and R′ is independently H, Me, Et, nPr, iPr, tBu, sBu, iBu, nBu, tAmyl, SiMe₃, SiMe₂H, or SiH₂Me. V(R₅Cp)₂X₂ may be prepared as described in J.C.S. Dalton 1980, 180-186. Z(N^{R, R′}-fmd) may be prepared by reaction of an alkyl alkali-metal, such as n-Butyl Lithium (nBuLi), with the corresponding formamidine molecule. The formamidine molecule may be prepared according to the procedure described in Organometallics 2004, 23, 3512-3520. The additions of the reactants may be done at low temperature, the temperature being below −50° C. The reaction may be done in a polar solvent, such as THF or diethylether. The precursor may be separated from alkali salts by extraction with a non polar solvent, such as pentane, hexane, cyclohexane, heptanes, benzene and toluene. The resulting Vanadium-containing film forming composition may be purified by vacuum sublimation, vacuum distillation, or by recrystallisation in a suitable solvent, such as THF, diethylether, pentane, hexane, cyclohexane, heptanes, benzene, toluene, or mixtures thereof.

The precursor may have the formula V(R₅Cp)₂(N^{R, R′} R″-amd):

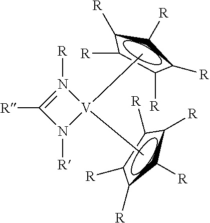

wherein each R, R′, and R″ is independently H, a C1 to C6 alkyl group, or SiR″′₃, with each R′″ independently being H or a C1 to C6 alkyl group. Preferably, each R, R′, or R″ is independently H, Me, Et, nPr, iPr, tBu, sBu, iBu, nBu, tAmyl, SiMe₃, SiMe₂H, or SiH₂Me. When R═R′ on the amidinate ligand, the formula is V(R₅Cp)₂(N^{R} R″-amd).

Exemplary Vanadium-containing film forming precursors include V(Cp)₂(N^{Me} Me-amd), V(Cp)₂(N^{Et} Me-amd), V(CP)₂(N^{iPr} Me-amd), V(CP)₂(N^{nPr} Me-amd), V(Cp)₂(N^{iBu} Me-amd), V(Cp)₂(N^{nBu} Me-amd), V(Cp)₂(N^{tBu} Me-amd), V(Cp)₂(N^{sBu} Me-amd), V(Cp)₂(N^{tAm} Me-amd), V(Cp)₂(N^{TMS} Me-amd), V(MeCp)₂(N^{Me} Me-amd), V(MeCp)₂(N^{Et} Me-amd), V(MeCp)₂(N^{iPr} Me-amd), V(MeCp)₂(N^{nPr} Me-amd), V(MeCp)₂(N^{iBu} Me-amd), V(MeCp)₂(N^{nBu} Me-amd), V(MeCp)₂(N^{tBu} Me-amd), V(MeCp)₂(N^{sBu} Me-amd), V(MeCp)₂(N^{tAm} Me-amd), V(MeCp)₂(N^{TMS} Me-amd), V(EtCp)₂(N^{Me} Me-amd), V(EtCp)₂(N^{Et} Me-amd), V(EtCp)₂(N^{iPr} Me-amd), V(EtCp)₂(N^{nPr} Me-amd), V(EtCp)₂(N^{iBu} Me-amd), V(EtCp)₂(N^{nBu} Me-amd), V(EtCp)₂(N^{tBu} Me-amd), V(EtCp)₂(N^{sBu} Me-amd),

V(EtCp)₂(N^{tAm} Me-amd), V(EtCp)₂(N^{TMS} Me-amd), V(iPrCp)₂(N^{Me} Me-amd), V(iPrCp)₂(N^{Et} Me-amd), V(iPrCp)₂(N^{iPr} Me-amd), V(iPrCp)₂(N^{nPr} Me-amd), V(iPrCp)₂(N^{iBu} Me-amd), V(iPrCp)₂(N^{nBu} Me-amd), V(iPrCp)₂(N^{tBu} Me-amd), V(iPrCp)₂(N^{sBu} Me-amd), V(iPrCp)₂(N^{tAm} Me-amd), V(iPrCp)₂(N^{TMS} Me-amd), V(tBuCp)₂(N^{Me} Me-amd), V(tBuCp)₂(N^{Et} Me-amd), V(tBuCp)₂(N^{iPr} Me-amd), V(tBuCp)₂(N^{nPr} Me-amd), V(tBuCp)₂(N^{iBu} Me-amd), V(tBuCp)₂(N^{nBu} Me-amd), V(tBuCp)₂(N^{tBu} Me-amd), V(tBuCp)₂(N^{sBu} Me-amd), V(tBuCp)₂(N^{tAm} Me-amd), V(tBuCp)₂(N^{TMS} Me-amd), V(iPr₃Cp)₂(N^{Me} Me-amd), V(iPr₃Cp)₂(N^{Et} Me-amd), V(iPr₃Cp)₂(N^{iPr} Me-amd), V(iPr₃Cp)₂(N^{nPr} Me-amd), V(iPr₃Cp)₂(N^{iBu} Me-amd), V(iPr₃Cp)₂(N^{nBu} Me-amd), V(iPr₃Cp)₂(N^{tBu} Me-amd), V(iPr₃Cp)₂(N^{sBu} Me-amd), V(iPr₃Cp)₂(N^{tAm} Me-amd), V(iPr₃Cp)₂(N^{TMS} Me-amd), V(Cp*)₂(N^{Me} Me-amd), V(Cp*)₂(N^{Et} Me-amd), V(Cp*)₂(N^{iPr} Me-amd), V(Cp*)₂(N_{nPr Me-amd}), V(Cp*)₂(N^{iBu} Me-amd), V(Cp*)²(^{nBu} Me-amd), V(CO₂(^{tBu} Me-amd), V(Cp*)₂(N^{sBu} Me-amd), V(Cp*)₂(N^{tAm} Me-amd), V(Cp*)₂(N^{TMS} Me-amd), V(Me₃SiCp)₂(N^{Me} Me-amd), V(Me₃SiCp)₂(N^{Et} Me-amd), V(Me₃SiCp)₂(N^{iPr} Me-amd), V(Me₃SiCp)₂(N^{nPr} Me-amd), V(Me₃SiCp)₂(N^{iBu} Me-amd), V(Me₃SiCp)₂(N^{nBu} Me-amd), V(Me₃SiCp)₂(N^{tBu} Me-amd), V(Me₃SiCp)₂(N^{sBu} Me-amd), V(Me₃SiCp)₂(N^{tAm} Me-amd), V(Me₃SiCp)₂(N^{TMS} Me-amd), V(Cp)(Cp*)(N^{Me} Me-amd), V(Cp)(iPr₃Cp)(N^{Me} Me-amd), V(Cp)(MeCp)(N^{Et} Me-amd), V(Cp)(EtCp)(N^{iPr} Me-amd), V(Cp)(iPrCp)(N^{nPr} Me-amd), V(Cp)(nPrCp)(N^{iBu} Me-amd), V(Cp)(iBuCp)(N^{nBu} Me-amd), V(Cp)(tBuCp)(N^{tBu} Me-amd), V(Cp)(tAmCp)(N^{sBu} Me-amd), V(Cp)₂(N^{iPr} Et-amd), V(Cp)₂(N^{iPr} nPr-amd), V(Cp)₂(N^{iPr} iPr-amd), V(Cp)₂(N^{iPr} tBu-amd), V(Cp)₂(N^{iPr} nBu-amd), V(Cp)₂(N^{iPr} iBu-amd), V(Cp)₂(N^{iPr} sBu-amd), V(MeCp)₂(N^{iPr} Et-amd), V(MeCp)₂(N^{iPr} nPr-amd), V(MeCp)₂(N^{iPr} iPr-amd), V(MeCp)₂(N^{iPr} tBu-amd), V(MeCp)₂(N^{iPr} nBu-amd), V(MeCp)₂(N^{iPr} iBu-amd), V(MeCp)₂(N^{iPr} sBu-amd), V(EtCp)₂(N^{iPr} Et-amd), V(EtCp)₂(N^{iPr} nPr-amd), V(EtCp)₂(N^{iPr} iPr-amd), V(EtCp)₂(N^{iPr} tBu-amd), V(EtCp)₂(N^{iPr} nBu-amd), V(EtCp)₂(N^{iPr} iBu-amd) or V(EtCp)₂(N^{iP}, sBu-amd).

These precursors may be synthesized by reacting V(R₅Cp)₂X₂ with two (2) equivalents of Z(N^{R, R′} R″-amd) wherein X is an halogen selected from the group consisting of F, Cl, Br and I; Z is an alkali metal selected from the group consisting of Li, Na and K; and each R, R′, and R″ is independently H, Me, Et, nPr, iPr, tBu, sBu, iBu, nBu, tAmyl, SiMe₃, SiMe₂H, or SiH₂Me. V(R₅Cp)₂X₂ is prepared as described in J.C.S. Dalton 1980, 180-186. Z(NI^{R, R′} R″-amd) may be prepared as described in Organometallics 1997, 16, 5183-5194. The additions of the reactants may be done at low temperature, the temperature being below −50° C. The reaction may be done in a polar solvent, such as THF and diethylether. The precursor may be separated from alkali salts by extraction with a non polar solvent, such as pentane, hexane, cyclohexane, heptanes, benzene and toluene. The resulting Vanadium-containing film forming compositions may be purified by vacuum sublimation, vacuum distillation, or by recrystallisation in a suitable solvent, such as THF, diethylether, pentane, hexane, cyclohexane, heptanes, benzene, toluene, or mixtures thereof.

The precursor may have the formula V(R₅Cp)₂(N^{R, R′}, N^{R″, R′″}-gnd):

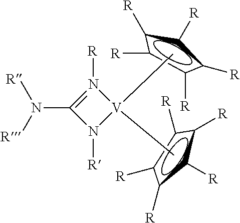

wherein each R, R′, R″ and R′″ is independently H, a C1 to C6 alkyl group, or SiR″″₃, with each R″″ being H or a C1 to C6 alkyl group. Preferably, each R, R′, or R″ is independently H, Me, Et, nPr, iPr, tBu, sBu, iBu, nBu, tAmyl, SiMe₃, SiMe₂H, or SiH₂Me. When R═R″ and R″═R″′ on the guanidinate ligand, the formula is V(R₅Cp)₂(N^{R}, N^{R}″-gnd).

Exemplary precursors include V(Cp)₂(N^{Me}, N^{Me}-gnd), V(Cp)₂(N^{Et}, N^{Me}-gnd), V(Cp)₂(N^{iPr}, N^{Me}-gnd), V(Cp)₂(N^{nPr}, N^{Me}-gnd), V(Cp)₂(N^{iBu}, N^{Me}-gnd), V(Cp)₂(N^{nBu}, N^{Me}-gnd), V(Cp)₂(N^{tBu}, N^{Me}-gnd), V(Cp)₂(N^{sBu}, N^{Me}-gnd), V(Cp)₂(N^{tAm}, N^{Me}-gnd), V(Cp)₂(N^{TMS}, N^{Me}-gnd), V(MeCp)₂(N^{Me}, N^{Me}-gnd), V(MeCp)₂(N^{Et}, N^{Me}-gnd), V(MeCp)₂(N^{iPr}, N^{Me}-gnd), V(MeCp)₂(N^{nPr}, N^{Me}-gnd), V(MeCp)₂(N^{iBu}, N^{Me}-gnd), V(MeCp)₂(N^{nBu}, N^{Me}-gnd), V(MeCp)₂(N^{tBu}, N^{Me}-gnd), V(MeCp)₂(N^{sBu}, N^{Me}-gnd), V(MeCp)₂(N^{tAm}, N^{Me}-gnd), V(MeCp)₂(N^{TMS}, N^{Me}-gnd), V(EtCp)₂(N^{Me}, N^{Me}-gnd), V(EtCp)₂(N^{Et}, N^{Me}-gnd), V(EtCp)₂(N^{iPr}, N^{Me}-gnd), V(EtCp)₂(N^{nPr}, N^{Me}-gnd), V(EtCp)₂(N^{iBu}, N^{Me}-gnd), V(EtCp)₂(N^{nBu}, N^{Me}-gnd), V(EtCp)₂(N^{tBu}, N^{Me}-gnd), V(EtCp)₂(N^{sBu}, N^{Me}-gnd), V(EtCp)₂(N^{tAm}, N^{Me}-gnd), V(EtCp)₂(N^{TMS}, N^{Me}-gnd), V(iPrCp)₂(N^{Me}, N^{Me}-gnd), V(iPrCp)₂(N^{Et}, N^{Me}-gnd), V(iPrCp)₂(N^{iPr}, N^{Me}-gnd), V(iPrCp)₂(N^{nPr}, N^{Me}-gnd), V(iPrCp)₂(N^{iBu}, N^{Me}-gnd), V(iPrCp)₂(N^{nBu}, N^{Me}-gnd), V(iPrCp)₂(N^{tBu}, N^{Me}-gnd), V(iPrCp)₂(N^{sBu}, N^{Me}-gnd), V(iPrCp)₂(N^{tAm}, N^{Me}-gnd), V(iPrCp)₂(N^{TMS}, N^{Me}-gnd), V(tBuCp)₂(N^{Me}, N^{Me}-gnd), V(tBuCp)₂(N^{Et}, N^{Me}-gnd), V(tBuCp)₂(N^{iPr}, N^{Me}-gnd), V(tBuCp)₂(N^{nPr}, N^{Me}-gnd), V(tBuCp)₂(N^{iBu}, N^{Me}-gnd), V(tBuCp)₂(N^{nBu}, N^{Me}-gnd), V(tBuCp)₂(N^{tBu}, N^{Me}-gnd), V(tBuCp)₂(N^{sBu}, N^{Me}-gnd), V(tBuCp)₂(N^{tAm}, N^{Me}-gnd), V(tBuCp)₂(N^{TMS}, N^{Me}-gnd), V(iPr₃Cp)₂(N^{Me}, N^{Me}-gnd), V(iPr₃Cp)₂(N^{Et}, N^{Me}-gnd), V(iPr₃Cp)₂(N^{iPr}, N^{Me}-gnd), V(iPr₃Cp)₂(N^{nPr}, N^{Me}-gnd), V(iPr₃Cp)₂(N^{iBu}, N^{Me}-gnd), V(iPr₃Cp)₂(N^{nBu}, N^{Me}-gnd), V(iPr₃Cp)₂(N^{tBu}, N^{Me}-gnd), V(iPr₃Cp)₂(N^{sBu}, N^{Me}-gnd), V(iPr₃Cp)₂(N^{tAm}, N^{Me}-gnd), V(iPr₃Cp)₂(N^{TMS}, N^{Me}-gnd), V(Cp*)₂(N^{Me}, N^{Me}-gnd), V(Cp*)₂(N^{Et}, N^{Me}-gnd), V(Cp*)₂(N^{iPr}, N^{Me}-gnd), V(Cp*)₂(N^{nPr}, N^{Me}-gnd), V(Cp*)₂(N^{iBu}, N^{Me}-gnd), V(Cp*)₂(^{nBu}, N^{Me}-gnd) V(Cp*)₂(^{tBu}, N^{Me}-gnd), V(Cp*)₂(N^{sBu}, N^{Me}-gnd), V(Cp*)₂(N^{tAm}, N^{Me}-gnd), V(Cp*)²(N^{TMS}, N^{Me}-_{gnd), V(}^{Me}₃SiCp)₂(N^{Me}, N^{Me}-gnd), V(^{Me}₃SiCp)₂(N^{Et}, N^{Me}-gnd), V(^{Me}₃SiCp)₂(N^{iPr}, N^{Me}-gnd), V(^{Me}₃SiCp)₂(N^{nPr}, N^{Me}-gnd), V(^{Me}₃SiCp)₂(N^{iBu}, N^{Me}-gnd), V(^{Me}₃SiCp)₂(N^{nBu}, N^{Me}-gnd), V(^{Me}₃SiCp)₂(N^{tBu}, N^{Me}-gnd), V(^{Me}₃SiCp)₂(N^{sBu}, N^{Me}-gnd), V(^{Me}₃SiCp)₂(N^{tAm}, N^{Me}-gnd), V(^{Me}₃SiCp)₂(N^{TMS}, N^{Me}-gnd), V(Cp)(Cp*)(N^{Me}, N^{Me}-gnd), V(Cp)(iPr₃Cp)(N^{Me}, N^{Me}-gnd), V(Cp)(MeCp)(N^{Et}, N^{Me}-gnd), V(Cp)(EtCp)(N^{iPr}, N^{Me}-gnd), V(Cp)(iPrCp)(N^{nPr}, N^{Me}-gnd), V(Cp)(nPrCp)(N^{iBu}, N^{Me}-gnd), V(Cp)(iBuCp)(N^{nBu}, N^{Me}-gnd), V(Cp)(tBuCp)(N^{tBu}, N^{Me}-gnd), V(Cp)(tAmCp)(N^{sBu}, N^{Me}-gnd), V(Cp)₂(N^{iPr}, N^{Me, Et}-gnd), V(Cp)₂(N^{iPr}, N^{Et}-gnd), V(Cp)₂(N^{iPr}, N^{nPr}-gnd), V(Cp)₂(N^{iPr}, N^{iPr}-gnd), V(MeCp)₂(N^{iPr}, N^{Me, Et}-gnd), V(MeCp)₂(N^{iPr}, N^{Et}-gnd), V(MeCp)₂(N^{iPr}, N^{nPr}-gnd), V(MeCp)₂(N^{iPr}, N^{iPr}-gnd), V(EtCp)₂(N^{iPr}, N^{Me, Et}-gnd), V(EtCp)₂(N^{iPr}, N^{Et}-gnd), V(EtCp)₂(N^{iPr}, N^{nPr}-gnd), or V(EtCp)₂(N^{iPr}, N^{iPr}-gnd).

These precursors may be synthesized by reacting V(R₅Cp)₂X₂ with two (2) equivalents of Z(N^{R, R′} N^{R″, R′″}-gnd) wherein X is an halogen selected from the group consisting of F, Cl, Br and I; Z is an alkali metal selected from the group consisting of Li, Na and K; and each R, R′, R″, and R″ is independently H, Me, Et, nPr, iPr, tBu, sBu, iBu, nBu, tAmyl, SiMe₃, SiMe₂H, or SiH₂Me. V(R₅Cp)₂X₂ is prepared as described in J.C.S. Dalton 1980, 180-186. Z(N^{R, R′} N^{R″, R′″}-gnd) may be prepared as described in Organometallics 2008, 27, 1596-1604. The additions of the reactants may be done at low temperature, the temperature being below −50° C. The reaction may be done in a polar solvent, such as THF and diethylether.

The precursor may be separated from alkali salts by extraction with a non polar solvent, such as pentane, hexane, cyclohexane, heptanes, benzene and toluene. The resulting Vanadium-containing film forming composition may be purified by vacuum sublimation, vacuum distillation, or by recrystallisation in a suitable solvent, such as THF, diethylether, pentane, hexane, cyclohexane, heptanes, benzene, toluene, or mixtures thereof.

Purity of the disclosed Vanadium-containing film forming compositions is preferably higher than 95% w/w (i.e., 95.0% w/w to 100.0% w/w), preferably greater than 98% w/w (98.0% w/w to 100.0% w/w), and more preferably greater than 99% w/w (99.0% w/w to 100.0% w/w). One of ordinary skill in the art will recognize that the purity may be determined by H NMR or gas or liquid chromatography with mass spectrometry. The disclosed Vanadium-containing film forming compositions may contain any of the following impurities: carbodiimides; alkylamines; dialkylamines; alkylimines; cyclopentadiene; dicyclopentadiene; THF; ether; pentane; cyclohexane; heptanes; benzene;

toluene; chlorinated metal compounds; lithium, sodium or potassium formamidinate; lithium, sodium or potassium amidinate; lithium, sodium or potassium guanidinate; or lithium, sodium or potassium cyclopentadienyl. The total quantity of these impurities is below 5% w/w (i.e. 0.0% w/w to 5.0% w/w), preferably below 2% w/w (i.e., 0.0% w/w to 2.0% w/w), and even more preferably below 1% w/w (i.e., 0.0% w/w to 1.0% w/w). The composition may be purified by recrystallisation, sublimation, distillation, and/or passing the gas or liquid through a suitable adsorbent, such as a 4A molecular sieve.

Purification of the disclosed Vanadium-containing film forming composition may also result in metal impurities at the 0 ppbw to 1 ppmw, preferably 0-500 ppbw (part per billion weight) level. These metal impurities include, but are not limited to, Aluminum (Al), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Indium (In), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti), Uranium (U), Vanadium (V) and Zinc (Zn).

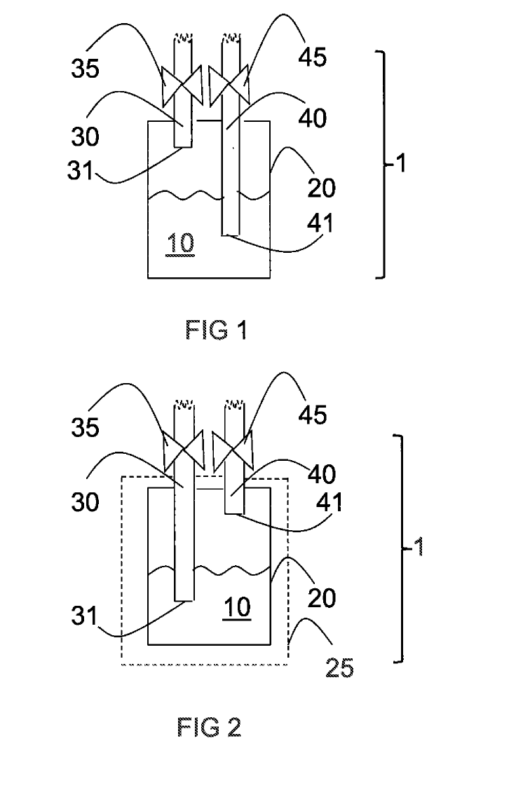

The Ta-containing film forming compositions or V-containing film forming compositions may be delivered to a semiconductor processing tool by the disclosed delivery devices. FIGS. 1 and 2 show two embodiments of the disclosed delivery devices 1.

FIG. 1 is a side view of one embodiment of the delivery device 1. In FIG. 1, the disclosed Ta-containing film forming compositions or V-containing film forming compositions 10 are contained within a container 20 having two conduits, an inlet conduit 30 and an outlet conduit 40. One of ordinary skill in the precursor art will recognize that the container 20, inlet conduit 30, and outlet conduit 40 are manufactured to prevent the escape of the gaseous form of the Ta-containing film forming compositions or V-containing film forming compositions 10, even at elevated temperature and pressure.

For pyrophoric compositions, as determined by section 33.3.1 of the United Nations Recommondations on the Transport of Dangerous Goods Manual of Tests and Criteria, 5^{th} Edition (2009), the delivery device must be leak tight and be equipped with valves that do not permit even minute amounts of the material. Suitable valves include spring-loaded or tied diaphragm valves. The valve may further comprise a restrictive flow orifice (RFO). The delivery device should be connected to a gas manifold and in an enclosure. The gas manifold should permit the safe evacuation and purging of the piping that may be exposed to air when the delivery device is replaced so that any residual amounts of the pyrophoric material do not react. The enclosure should be equipped with sensors and fire control capability to control the fire in the case of a pyrophoric material release. The gas manifold should also be equipped with isolation valves, vacuum generators, and permit the introduction of a purge gas at a minimum.

The delivery device fluidly connects to other components of the semiconductor processing tool, such as the gas cabinet disclosed above, via valves 35 and 45. Preferably, the delivery device 20, inlet conduit 30, valve 35, outlet conduit 40, and valve 45 are made of 316L EP or 304 stainless steel.

However, one of ordinary skill in the art will recognize that other non-reactive materials may also be used in the teachings herein and that any corrosive Ta-containing film forming compositions or V-containing film forming compositions 10 may require the use of more corrosion-resistant materials, such as Hastelloy or Inconel.

In FIG. 1, the end 31 of inlet conduit 30 is located above the surface 11 of the Ta-containing film forming compositions or V-containing film forming compositions 10, whereas the end 41 of the outlet conduit 40 is located below the surface 11 of the Ta-containing film forming compositions or V-containing film forming compositions 10. In this embodiment, the Ta-containing film forming compositions or V-containing film forming compositions 10 is preferably in liquid form. An inert gas, including but not limited to nitrogen, argon, helium, and mixtures thereof, may be introduced into the inlet conduit 30. The inert gas pressurizes the delivery device 20 so that the liquid Ta-containing film forming compositions or V-containing film forming compositions 10 is forced through the outlet conduit 40 and to components in the semiconductor processing tool (not shown). The semiconductor processing tool may include a vaporizer which transforms the liquid Ta-containing film forming compositions or V-containing film forming compositions 10 into a vapor, with or without the use of a carrier gas such as helium, argon, nitrogen or mixtures thereof, in order to deliver the vapor to a chamber where a wafer to be repaired is located and treatment occurs in the vapor phase. Alternatively, the liquid Ta-containing film forming compositions or V-containing film forming compositions 10 may be delivered directly to the wafer surface as a jet or aerosol.

FIG. 2 is a side view of a second embodiment of the delivery device 1. In FIG. 2, the end 31 of inlet conduit 30 is located below the surface 11 of the Ta-containing film forming compositions or V-containing film forming compositions 10, whereas the end 41 of the outlet conduit 40 is located above the surface 11 of the Ta-containing film forming compositions or V-containing film forming compositions 10. FIG. 2 also includes an optional heating element 25, which may increase the temperature of the Ta-containing film forming compositions or V-containing film forming compositions 10. In this embodiment, the Ta-containing film forming compositions or V-containing film forming compositions 10 may be in solid or liquid form. An inert gas, including but not limited to nitrogen, argon, helium, and mixtures thereof, is introduced into the inlet conduit 30. The inert gas bubbles through the Ta-containing film forming compositions or V-containing film forming compositions 10 and carries a mixture of the inert gas and vaporized Ta-containing film forming compositions or V-containing film forming compositions 10 to the outlet conduit 40 and on to the components in the semiconductor processing tool.

Both FIGS. 1 and 2 include valves 35 and 45. One of ordinary skill in the art will recognize that valves 35 and 45 may be placed in an open or closed position to allow flow through conduits 30 and 40, respectively. Either delivery device 1 in FIG. 1 or 2, or a simpler delivery device having a single conduit terminating above the surface of any solid or liquid present, may be used if the Ta-containing film forming compositions or V-containing film forming compositions 10 is in vapor form or if sufficient vapor pressure is present above the solid/liquid phase. In this case, the Ta-containing film forming compositions or V-containing film forming compositions 10 is delivered in vapor form through the conduit 30 or 40 simply by opening the valve 35 in FIG. 1 or 45 in FIG. 2, respectively. The delivery device 1 may be maintained at a suitable temperature to provide sufficient vapor pressure for the Ta-containing film forming compositions or V-containing film forming compositions 10 to be delivered in vapor form, for example by the use of an optional heating element 25.

While FIGS. 1 and 2 disclose two embodiments of the delivery device 1, one of ordinary skill in the art will recognize that the inlet conduit 30 and outlet conduit 40 may both be located above or below the surface 11 of the Ta-containing film forming compositions or V-containing film forming compositions 10 without departing from the disclosure herein. Furthermore, inlet conduit 30 may be a filling port. Finally, one of ordinary skill in the art will recognize that the disclosed Ta-containing film forming compositions or V-containing film forming compositions may be delivered to semiconductor processing tools using other delivery devices, such as the ampoules disclosed in WO 2006/059187 to Jurcik et al., without departing from the teachings herein.

Also disclosed are methods for forming Tantalum- or Vanadium- containing layers on a substrate using a vapor deposition process. The method may be useful in the manufacture of semiconductor, photovoltaic, LCD-TFT, or flat panel type devices. The disclosed Tantalum- or Vanadium- containing film forming compositions may be used to deposit Tantalum- or Vanadium-containing films using any deposition methods known to those of skill in the art. Examples of suitable vapor deposition methods include chemical vapor deposition (CVD) or atomic layer deposition (ALD). Exemplary CVD methods include thermal CVD, plasma enhanced CVD (PECVD), pulsed CVD (PCVD), low pressure CVD (LPCVD), sub-atmospheric CVD (SACVD) or atmospheric pressure CVD (APCVD), hot-wire CVD (HWCVD, also known as cat-CVD, in which a hot wire serves as an energy source for the deposition process), radicals incorporated CVD, and combinations thereof. Exemplary ALD methods include thermal ALD, plasma enhanced ALD (PEALD), spatial isolation ALD, hot-wire ALD (HWALD), radicals incorporated ALD, and combinations thereof. Super critical fluid deposition may also be used. The deposition method is preferably ALD, PE-ALD, or spatial ALD in order to provide suitable step coverage and film thickness control.

The disclosed Tantalum- or Vanadium-containing film forming compositions may be supplied either in neat form or in a blend with a suitable solvent, such as ethyl benzene, xylene, mesitylene, decalin, decane, dodecane. The disclosed precursors may be present in varying concentrations in the solvent.

The neat or blended Tantalum- or Vanadium-containing film forming compositions are introduced into a reactor in vapor form by conventional means, such as tubing and/or flow meters. The vapor form may be produced by vaporizing the neat or blended composition through a conventional vaporization step such as direct vaporization, distillation, or by bubbling, or by using a sublimator such as the one disclosed in PCT Publication WO2009/087609 to Xu et al. The neat or blended composition may be fed in liquid state to a vaporizer where it is vaporized before it is introduced into the reactor. Alternatively, the neat or blended composition may be vaporized by passing a carrier gas into a container containing the composition or by bubbling the carrier gas into the composition. The carrier gas may include, but is not limited to, Ar, He, N₂,and mixtures thereof. Bubbling with a carrier gas may also remove any dissolved oxygen present in the neat or blended composition. The carrier gas and composition are then introduced into the reactor as a vapor.

If necessary, the container containing the disclosed composition may be heated to a temperature that permits the composition to be in its liquid phase and to have a sufficient vapor pressure. The container may be maintained at temperatures in the range of, for example, approximately 0° C. to approximately 150° C. Those skilled in the art recognize that the temperature of the container may be adjusted in a known manner to control the amount of precursor vaporized.

The reactor may be any enclosure or chamber within a device in which deposition methods take place such as without limitation, a parallel-plate type reactor, a cold-wall type reactor, a hot-wall type reactor, a single-wafer reactor, a multi-wafer reactor (i.e., a batch reactor), or other types of deposition systems under conditions suitable to cause the precursors to react and form the layers.

The reactor contains one or more substrates onto which the films will be deposited. A substrate is generally defined as the material on which a process is conducted. The substrates may be any suitable substrate used in semiconductor, photovoltaic, flat panel, or LCD-TFT device manufacturing. Examples of suitable substrates include wafers, such as silicon, silica, glass, or GaAs wafers. The wafer may have one or more layers of differing materials deposited on it from a previous manufacturing step. For example, the wafers may include silicon layers (crystalline, amorphous, porous, etc.), silicon oxide layers, silicon nitride layers, silicon oxy nitride layers, carbon doped silicon oxide (SiCOH) layers, or combinations thereof. Additionally, the wafers may include copper layers or noble metal layers (e.g. platinum, palladium, rhodium, or gold). The wafers may include barrier layers, such as manganese, manganese oxide, etc. Plastic layers, such as poly(3,4-ethylenedioxythiophene)poly(styrenesulfonate) [PEDOT:PSS] may also be used. The layers may be planar or patterned. The disclosed processes may deposit the Tantalum- or Vanadium-containing layer directly on the wafer or directly on one or more than one (when patterned layers form the substrate) of the layers on top of the wafer. Furthermore, one of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates. For example, a Tantalum Nitride film may be deposited onto a Si layer. In subsequent processing, a zirconium oxide layer may be deposited on the Tantalum Nitride layer, a second Tantalum Nitride layer may be deposited on the zirconium oxide layer forming a TaN/ZrO₂/TaN stack used in DRAM capacitors. The substrate may be patterned to include vias or trenches having high aspect ratios. For example, a conformal Ta-containing film, such as TaN, may be deposited using any ALD technique on a through silicon via (TSV) having an aspect ratio ranging from approximately 20:1 to approximately 100:1.

The temperature and the pressure within the reactor are held at conditions suitable for vapor depositions. In other words, after introduction of the vaporized compositions into the chamber, conditions within the chamber are such that at least part of the precursor is deposited onto the substrate to form a Tantalum- or Vanadium-containing film. For instance, the pressure in the reactor may be held between about 1 Pa and about 10⁵ Pa, more preferably between about 25 Pa and about 10³ Pa, as required per the deposition parameters. Likewise, the temperature in the reactor may be held between about 100° C. and about 500° C., preferably between about 150° C. and about 400° C. One of ordinary skill in the art will recognize that “at least part of the precursor is deposited” means that some or all of the precursor reacts with or adheres to the substrate.

The temperature of the reactor may be controlled by either controlling the temperature of the substrate holder or controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 100° C. to approximately 500° C. When a plasma deposition process is utilized, the deposition temperature may range from approximately 150° C. to approximately 400° C. Alternatively, when a thermal process is performed, the deposition temperature may range from approximately 200° C. to approximately 500° C.

In addition to the disclosed Ta- or V-containing film forming compositions, a reactant may also be introduced into the reactor. The reactant may be an oxidizing gas such as one of O₂, O₃, H₂O, H₂O₂, NO, N₂O, NO₂, oxygen containing radicals such as O⁻ or OH⁻, NO, NO₂,carboxylic acids, formic acid, acetic acid, propionic acid, and mixtures thereof. Preferably, the oxidizing gas is selected from the group consisting of O₂, O₃, H₂O, H₂O₂, oxygen containing radicals thereof such as O⁻ or OH⁻, and mixtures thereof.

Alternatively, the reactant may be a reducing gas such as one of H₂, H₂CO, NH₃, SiH₄, Si₂H₆, Si₃H₈, (CH₃)₂SiH₂, (C₂H₅)₂SiH₂, (CH₃)SiH₃, (C₂H₅)SiH₃, phenyl silane, N₂H₄, N(SiH₃)₃, N(CH₃)H₂, N(C₂H₅)H₂, N(CH₃)₂H, N(C₂H₅)₂H, N(CH₃)₃, N(C₂H₅)₃, (SiMe₃)₂NH, (CH₃)HNNH₂, (CH₃)₂NNH₂, phenyl hydrazine, N-containing molecules, B₂H₆, 9-borabicyclo[3,3,1]nonane, dihydrobenzenfuran, pyrazoline, trimethylaluminium, dimethylzinc, diethylzinc, radical species thereof, and mixtures thereof. Preferably, the reducing as is H₂, NH₃, SiH₄, Si₂H₆, Si₃H₈, SiH₂Me₂, SiH₂Et₂, N(SiH₃)₃, hydrogen radicals thereof, or mixtures thereof.

The reactant may be treated by a plasma, in order to decompose the reactant into its radical form. N₂ may also be utilized as a reducing gas when treated with plasma. For instance, the plasma may be generated with a power ranging from about 50 W to about 500 W, preferably from about 100 W to about 400 W. The plasma may be generated or present within the reactor itself. Alternatively, the plasma may generally be at a location removed from the reactor, for instance, in a remotely located plasma system. One of skill in the art will recognize methods and apparatus suitable for such plasma treatment.

For example, the reactant may be introduced into a direct plasma reactor, which generates plasma in the reaction chamber, to produce the plasma-treated reactant in the reaction chamber. Exemplary direct plasma reactors include the Titan™ PECVD System produced by Trion Technologies. The reactant may be introduced and held in the reaction chamber prior to plasma processing. Alternatively, the plasma processing may occur simultaneously with the introduction of the reactant. In-situ plasma is typically a 13.56 MHz RF inductively coupled plasma that is generated between the showerhead and the substrate holder. The substrate or the showerhead may be the powered electrode depending on whether positive ion impact occurs. Typical applied powers in in-situ plasma generators are from approximately 30 W to approximately 1000 W. Preferably, powers from approximately 30 W to approximately 600 W are used in the disclosed methods. More preferably, the powers range from approximately 100 W to approximately 500 W. The disassociation of the reactant using in-situ plasma is typically less than achieved using a remote plasma source for the same power input and is therefore not as efficient in reactant disassociation as a remote plasma system, which may be beneficial for the deposition of Tantalum- or Vanadium-containing films on substrates easily damaged by plasma.

Alternatively, the plasma-treated reactant may be produced outside of the reaction chamber. The MKS Instruments' ASTRONi® reactive gas generator may be used to treat the reactant prior to passage into the reaction chamber. Operated at 2.45 GHz, 7kW plasma power, and a pressure ranging from approximately 0.5 Torr to approximately 10 Torr, the reactant O₂ may be decomposed into two O radicals. Preferably, the remote plasma may be generated with a power ranging from about 1 kW to about 10 kW, more preferably from about 2.5 kW to about 7.5 kW.

The vapor deposition conditions within the chamber allow the precursor and the reactant to react and form a Tantalum- or Vanadium-containing film on the substrate. In some embodiments, Applicants believe that plasma-treating the reactant may provide the reactant with the energy needed to react with the precursor.

Depending on what type of film is desired to be deposited, an additional precursor compound may be introduced into the reactor. The precursor may be used to provide additional elements to the Tantalum- or Vanadium-containing film. The additional elements may include lanthanides (Ytterbium, Erbium, Dysprosium, Gadolinium, Praseodymium, Cerium, Lanthanum, Yttrium), zirconium, germanium, silicon, titanium, manganese, ruthenium, bismuth, lead, magnesium, aluminum, or mixtures of these. When an additional precursor compound is utilized, the resultant film deposited on the substrate contains the Tantalum or Vanadium in combination with at least one additional element.

The Tantalum- or Vanadium-containing film forming compositions and reactants may be introduced into the reactor either simultaneously (chemical vapor deposition), sequentially (atomic layer deposition) or different combinations thereof. The reactor may be purged with an inert gas between the introduction of the composition and the introduction of the reactant. Alternatively, the reactant and the composition may be mixed together to form a reactant/composition mixture, and then introduced to the reactor in mixture form. Another example is to introduce the reactant continuously and to introduce the Tantalum- or Vanadium- containing film forming composition by pulse (pulsed chemical vapor deposition).

The vaporized compositions and the reactants may be pulsed sequentially or simultaneously (e.g. pulsed CVD) into the reactor. Each pulse of the composition may last for a time period ranging from about 0.01 seconds to about 10 seconds, alternatively from about 0.3 seconds to about 3 seconds, alternatively from about 0.5 seconds to about 2 seconds. In another embodiment, the reactant may also be pulsed into the reactor. In such embodiments, the pulse of each gas may last for a time period ranging from about 0.01 seconds to about 10 seconds, alternatively from about 0.3 seconds to about 3 seconds, alternatively from about 0.5 seconds to about 2 seconds. In another alternative, the vaporized compositions and reactants may be simultaneously sprayed from a shower head under which a susceptor holding several wafers is spun (spatial ALD).

Depending on the particular process parameters, deposition may take place for a varying length of time. Generally, deposition may be allowed to continue as long as desired or necessary to produce a film with the necessary properties. Typical film thicknesses may vary from several angstroms to several hundreds of microns, depending on the specific deposition process. The deposition process may also be performed as many times as necessary to obtain the desired film.

In one non-limiting exemplary CVD type process, the vapor phase of the disclosed Tantalum- or Vanadium-containing film forming composition and a reactant are simultaneously introduced into the reactor. The two react to form the resulting Tantalum- or Vanadium-containing film. When the reactant in this exemplary CVD process is treated with a plasma, the exemplary CVD process becomes an exemplary PECVD process. The reactant may be treated with plasma prior or subsequent to introduction into the chamber.

In one non-limiting exemplary ALD type process, the vapor phase of the disclosed Tantalum- or Vanadium-containing film forming composition is introduced into the reactor, where it is contacted with a suitable substrate. Excess composition may then be removed from the reactor by purging and/or evacuating the reactor. A desired gas (for example, H₂) is introduced into the reactor where it reacts with the physic- or chemisorbed precursor in a self-limiting manner. Any excess reducing gas is removed from the reactor by purging and/or evacuating the reactor. If the desired film is a pure Tantalum or Vanadium film, this two-step process may provide the desired film thickness or may be repeated until a film having the necessary thickness has been obtained.

Alternatively, if the desired film contains the Tantalum or Vanadium transition metal and a second element, the two-step process above may be followed by introduction of the vapor of an additional precursor compound into the reactor. The additional precursor compound will be selected based on the nature of the Tantalum-containing film being deposited. After introduction into the reactor, the additional precursor compound is contacted with the substrate. Any excess precursor compound is removed from the reactor by purging and/or evacuating the reactor. Once again, a desired gas may be introduced into the reactor to react with the physic- or chemisorbed precursor compound. Excess gas is removed from the reactor by purging and/or evacuating the reactor. If a desired film thickness has been achieved, the process may be terminated. However, if a thicker film is desired, the entire four-step process may be repeated. By alternating the provision of the Tantalum- or Vanadium-containing film forming composition, additional precursor compound, and reactant, a film of desired composition and thickness can be deposited.

When the reactant in this exemplary ALD process is treated with a plasma, the exemplary ALD process becomes an exemplary PEALD process. The reactant may be treated with plasma prior or subsequent to introduction into the chamber.

In a second non-limiting exemplary ALD type process, the vapor phase of one of the disclosed Tantalum- or Vanadium-containing film forming composition, for example Tantalum bis(ethylcyclopentadienyl) diisopropylamidinate (Ta(EtCp)₂(N^{iPr} Me-amd)) or Vanadium bis(ethylcyclopentadienyl) diisopropylamidinate, is introduced into the reactor, where it is contacted with a Si substrate. Excess precursor may then be removed from the reactor by purging and/or evacuating the reactor. A desired gas (for example, NH₃) is introduced into the reactor where it reacts with the absorbed precursor in a self-limiting manner to form a Tantalum Nitride or Vanadium Nitride film. Any excess NH₃ gas is removed from the reactor by purging and/or evacuating the reactor. These two steps may be repeated until the Tantalum Nitride or Vanadium Nitride film obtains a desired thickness, typically around 10 angstroms. ZrO₂ may then be deposited on the TaN or VN film. For example, ZrCp(NMe₂)₃ may serve as the Zr precursor. The second non-limiting exemplary ALD process described above using Ta(EtCp)₂(N^{iPr} Me-amd) or V(EtCp)₂(N^{iPr} Me-amd) and NH₃ may then be repeated on the ZrO₂ layer. The resulting TaN/ZrO₂/TaN or VN/ZrO₂/VN stack may be used in DRAM capacitors.

The Ta- or V-containing films resulting from the processes discussed above may include a pure Tantalum transition metal, a pure Vanadium transition metal, a Tantalum transition metal silicide (TaₖSiₗ), a Vanadium transition metal silicide (VₖSiₗ), a Ta transition metal oxide (TaₙOₘ), a V transition metal oxide (VₙOₘ), a Ta transition metal nitride (TaₙNₚ), a V transition metal nitride (VₒNₚ), a Ta transition metal carbide (Ta_{q}Cᵣ), a V transition metal carbide (V_{q}Cᵣ), a Ta transition metal carbonitride (TaCᵣNₚ), or a V transition metal carbonitride (VCᵣNₚ) film, wherein k, l, m, n, o, p, q, and r are integers which inclusively range from 1 to 6. One of ordinary skill in the art will recognize that by judicial selection of the appropriate disclosed Ta- or V-containing film forming compostion, optional precursor compounds, and reactant species, the desired film composition may be obtained.

Upon obtaining a desired film thickness, the film may be subject to further processing, such as thermal annealing, furnace-annealing, rapid thermal annealing, UV or e-beam curing, and/or plasma gas exposure. Those skilled in the art recognize the systems and methods utilized to perform these additional processing steps. For example, the Ta- or V-containing film may be exposed to a temperature ranging from approximately 200° C. and approximately 1000° C. for a time ranging from approximately 0.1 second to approximately 7200 seconds under an inert atmosphere, a H-containing atmosphere, a N-containing atmosphere, an O-containing atmosphere, or combinations thereof. Most preferably, the temperature is 400° C. for 3600 seconds under a H-containing atmosphere or an O-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the Ta- or V-containing film. This in turn tends to improve the resistivity of the film.

After annealing, the Tantalum- or Vandium-containing films deposited by any of the disclosed processes may have a bulk resistivity at room temperature of approximately 50 μohm·cm to approximately 1,000 μohm·cm. Room temperature is approximately 20° C. to approximately 28° C. depending on the season. Bulk resistivity is also known as volume resistivity. One of ordinary skill in the art will recognize that the bulk resistivity is measured at room temperature on Ta or V films that are typically approximately 50 nm thick. The bulk resistivity typically increases for thinner films due to changes in the electron transport mechanism. The bulk resistivity also increases at higher temperatures.

In another alternative, the disclosed compositions may be used as doping or implantation agents. Part of the precursor in the disclosed compositions may be deposited on top of the film to be doped, such as an indium oxide (In₂O₃) film, tantalum dioxide (TaO₂), vanadium dioxide (VO₂) film, a titanium oxide film, a copper oxide film, or a tin dioxide (Sn0₂) film. The Tantalum or Vanadium then diffuses into the film during an annealing step to form the Tantalum or Vanadium-doped films {(Ta)In₂O₃, (Ta)VO₂, (Ta)TiO, (Ta)CuO, (Ta)SnO₂, (V)In₂O₃, (V)TaO₂, (V)TiO, (V)CuO, or (V)SnO₂}. See, e.g., US2008/0241575 to Lavoie et al., the doping method of which is incorporated herein by reference in its entirety. Alternatively, high energy ion implantation using a variable energy radio frequency quadrupole implanter may be used to dope the Tantalum or Vanadium of the disclosed compositions into a film. See, e.g., Kensuke et al., JVSTA 16(2) March/April 1998, the implantation method of which is incorporated herein by reference in its entirety. In another alternative, plasma doping, pulsed plasma doping or plasma immersion ion implantation may be performed using the disclosed composition. See, e.g., Felch et al., Plasma doping for the fabrication of ultra-shallow junctions Surface Coatings Technology, 156 (1-3) 2002, pp. 229-236, the doping method of which is incorporated herein by reference in its entirety.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

We claim:

1. A Tantalum- or Vanadium-containing film forming composition comprising a precursor having the formula
M(R₅Cp)₂(L)
wherein M is Ta or V; each R is independently H, an alkyl group, or R′₃Si, with each R′ independently being H or an alkyl group; and L is selected from the group consisting of a formamidinate (N^{R, R′}-fmd or N^{R}-fmd when R═R′), amidinate (N^{R, R′} R″-amd or N^{R} R″-amd when R═R′), and guanidinate (N^{R, R′}, N^{R″, R′″}-gnd or or N^{R}, N^{R″}-gnd when R═R′ and R″═R″′).

2. The Tantalum- or Vanadium-containing film forming composition of claim 1, wherein the precursor has the formula M(R₅Cp)₂(N^{R, R′}-fmd) or M(R₅Cp)₂(N^{R}-fmd) when R═R′.

3. The Tantalum- or Vanadium-containing film forming composition of claim 2, wherein the precursor is Ta(EtCp)₂(N^{iPr}-fmd) or V(EtCp)₂(N^{iPr}-fmd).

4. The Tantalum- or Vanadium-containing film forming composition of claim 1, wherein the precursor has the formula M(R₅Cp)₂(N^{R, R′} R″-amd) or M(R₅Cp)₂(N^{R} R″-amd) when R═R′.

5. The Tantalum- or Vanadium containing film forming composition of claim 4, wherein the precursor is Ta(EtCp)₂(N^{iPr} Me-amd) or V(EtCp)₂(N^{iPr} Me-amd).

6. The Tantalum- or Vanadium containing film forming composition of claim 1, wherein the precursor has the formula M(R₅Cp)₂(N^{R, R′}, N^{R″, R′″}-gnd) or M(R₅Cp)₂(N^{R}, N^{R″}-gnd) when R═R′ and R″═R′″.

7. The Tantalum- or Vanadium-containing film forming composition of claim 6, wherein the precursor is Ta(EtCp)₂(N^{iPr}, N^{Me}-gnd) or V(EtCp)₂(N^{iPr}, N^{Me}-gnd).

8. The Tantalum- or Vanadium-containing film forming composition of claim 1, the composition comprising between approximately 95% w/w and approximately 100.0% w/w of the precursor.

9. A method of forming a Tantulum- or Vanadium-containing film, the method comprising introducing into a reactor having a substrate therein a vapor of a Tantalum- or Vanadium-containing film forming composition comprising a precursor having the formula:
M(R₅Cp)₂(L)
wherein M is Ta or V; each R is independently H, an alkyl group, or R′₃Si, with each R′ independently being H or an alkyl group; and L is selected from the group consisting of a formamidinate (N^{R, R′}-fmd or N^{R}-fmd when R═R′), amidinate (N^{R, R′} R″-amd or N^{R} R″-amd when R═R′), and guanidinate (N^{R, R′} N^{R″, R′″}-gnd or N^{R}, N^{R″}-gnd when R═R′ and R″═R″′); and
depositing at least part of the precursor onto the substrate.

10. The method of claim 9, further comprising introducing a reactant into the reactor.

11. The method of claim 10, wherein the reactant is selected from the group consisting of N₂, N₂H₄, NH₃, N(SiH₃)₃, nitrogen radicals thereof, and mixtures thereof.

12. The method of claim 10, wherein the reactant is selected from the group consisting of O₂, O₃, H₂O, H₂O₂ NO, N₂O, NO₂, oxygen radicals thereof, and mixtures thereof.

13. The method of claim 10, wherein the Tantulum- or Vanadium-containing film forming composition and the reactant are introduced into the reactor simultaneously and the reactor is configured for chemical vapor deposition.

14. The method of claim 10, wherein the Tantulum- or Vanadium-containing film forming composition and the reactant are introduced into the chamber sequentially and the reactor is configured for atomic layer deposition.

15. The method of claim 9, wherein the substrate is an electrode.

16. The method of claim 9, wherein the substrate is TiN, NbN or Ru and the Tantulum- or Vanadium-containing film forming composition is used to form a DRAM capacitor.

17. The method of of claim 9, wherein the substrate is silicon oxide (SiO₂).

18. The method of claim 17, wherein the Tantulum-containing film forming composition is used to form a hard mark used in Double or triple Patterning Technology

19. The method of claim 10, further comprising plasma treating the reactant.

20. The method of claim 10, wherein the reactant is O₃ and the precursor is selected from the group consisting of Ta(EtCp)₂(N^{iPr} Me-amd), Ta(iPrCp)₂(N^{Pr} Me-amd), V(EtCp)₂(N^{Pr} Me-amd), V(iPrCp)₂(N^{Pr} Me-amd), and combinations thereof.
